(19) United States
(12) Patent Application Publication
(10) Pub. No.: US 2025/0216627 A1
(43) Pub. Date: Jul. 3, 2025

(54) FIBER ARRAY UNIT ASSEMBLY AND CO-PACKAGED OPTICS USING THE SAME

(71) Applicant: Celestial AI Inc., Santa Clara, CA (US)

(72) Inventors: Subal Sahni, La Jolla, CA (US); Shuhe Li, Pasadena, CA (US)

(21) Appl. No.: 19/006,052

(22) Filed: Dec. 30, 2024

Related U.S. Application Data
(60) Provisional application No. 63/616,465, filed on Dec. 29, 2023.

(51) Int. Cl. G02B 6/42; G02B 6/43

(52) U.S. Cl. CPC G02B 6/4213; G02B 6/4226; G02B 6/4259; G02B 6/4293; G02B 6/43

(57) ABSTRACT

An assembly for coupling optical fibers to photonic ports on a surface of a photonic integrated circuits includes optical components for directing optical signals between a fiber array unit and the PIC, the optical components including a pair of lens arrays and a polarizing beam splitter. Non-polarization maintaining fibers may be used with the assembly.

### CROSS-REFERENCE TO RELATED APPLICATIONS

This application claims the benefit of priority to Provisional Application No. 63/616,465, filed on Dec. 29, 2023, the contents of which are hereby incorporated by reference.

### BACKGROUND

Demands for artificial intelligence (AI) computing, such as machine learning (ML) and deep learning (DL), are increasing faster than they can be met by increases in available processing capacity. This rising demand and the growing complexity of AI models drive the need to connect many chips into a system where the chips can send data between each other with low latency and at high speed. Performance when processing a workload is limited by memory and interconnect bandwidth. In many conventional systems, data movement leads to significant power consumption, poor performance, and excessive latency.

### SUMMARY

Implementations of this specification provide apparatus, systems, and techniques for photonic interconnects. The photonic interconnects can be used to route data between nodes on a same chip (intra-chip routing) and between nodes on different chips (inter-chip routing). Both inter-chip and intra-chip routing can include routing data over electrical channels, over photonic channels, or over both electrical channels and photonic channels, between nodes, chips, packages, systems, and any suitable platforms.

The photonic interconnect techniques enable disaggregation of compute and memory, which allows each component to be leveraged and scaled effectively to deliver more than one order of magnitude higher bandwidth and memory capacity while reducing latency and power consumption by up to one order of magnitude compared to existing optical interconnect alternatives and copper. For example, the techniques can deliver data directly to the point of compute using the photonic interconnects, while supporting high memory bandwidth and latency requirements at low single digit pJ/bit power, which enables terabyte class bandwidth between compute nodes at low latency and power. The techniques can address key concerns across performance and energy efficiency to ensure systems, models and algorithms, e.g., hyperscalers, data centers, artificial intelligence (AI) models, to continue to innovate and scale.

The photonic interconnects feature fiber array unit (FAU) assemblies that facilitate use of non-polarization maintain fibers for carrying optical signals between nodes and light sources. In certain implementations, the FAU assemblies feature detachable sub-assemblies facilitating manual detachment and reattachment of FAUs to photonic integrated circuits.

Other features and advantages will be apparent from the following description, the drawings, and the claims.

### BRIEF DESCRIPTION OF THE DRAWINGS

FIG. 1A is a diagram schematically illustrating an example system including first and second systems configured to be connected with photonic interconnects for data communication;

FIG. 1B is a diagram schematically illustrating an example of circuit packages;

FIG. 2A is a diagram illustrating an example bi-directional photonic channel for light with a single wavelength;

FIG. 2B is a diagram illustrating an example bi-directional photonic channel for light with multiple wavelengths using wavelength-division multiplexing (WDM) technology;

FIG. 3A is a diagram illustrating an example structural circuit package;

FIG. 3B is a diagram schematically illustrating an example circuit package with more details;

FIG. 3C is a diagram schematically illustrating an example of a circuit package implementing an intra-chip bidirectional photonic channel;

FIG. 4A is a diagram schematically illustrating an example fiber array unit (FAU) assembly for attaching a fiber array to a surface of a photonic integrated circuit (PIC).

FIG. 4B is a diagram schematically illustrating components of a FAU assembly for coupling light from a non-polarization maintaining optical fiber into a PIC.

FIGS. 5A-5D are diagrams schematically illustrating an example FAU assembly for coupling light from a non-polarization maintaining optical fiber into a PIC in cross-section.

FIG. 6 is a diagram schematically illustrating another example FAU assembly for coupling light from a non-polarization maintaining optical fiber into a PIC in cross-section.

FIGS. 7A-7B are diagrams showing, in perspective view, an example FAU assembly for coupling light from a non-polarization maintaining optical fiber into a PIC.

FIGS. 8A-8D are diagrams showing, in perspective view, a further example FAU assembly for coupling light from a non-polarization maintaining optical fiber into a PIC.

FIG. 9 is a diagram schematically illustrating another example FAU assembly for coupling light from a non-polarization maintaining optical fiber into a PIC in cross-section.

FIG. 10 is a diagram schematically illustrating another example FAU assembly for coupling light from a non-polarization maintaining optical fiber into a PIC in cross-section.

FIG. 11 is a diagram schematically illustrating another example FAU assembly for coupling light from a non-polarization maintaining optical fiber into a PIC in cross-section.

FIG. 12 is a diagram schematically illustrating another example FAU assembly for coupling light from a non-polarization maintaining optical fiber into a PIC in cross-section.

FIGS. 13A-13B are diagrams showing, in perspective view, a further example FAU assembly for coupling light from a non-polarization maintaining optical fiber into a PIC.

FIG. 14 is a diagram showing, in perspective view, a further example FAU assembly for coupling light from a non-polarization maintaining optical fiber into a PIC.

FIGS. 15A-15F are diagrams schematically illustrating steps in an example fabrication process for making a FAU assembly in cross-section.

FIG. 16 is a diagram schematically illustrating an example FAU assembly composed of detachable sub-assemblies in cross-section.

FIG. 17 is a diagram schematically illustrating another example FAU assembly composed of detachable sub-assemblies in cross-section.

FIG. 18 is a diagram schematically illustrating a further example FAU assembly composed of detachable sub-assemblies in cross-section.

Like reference numbers and designations in the various drawings indicate like elements.

### DETAILED DESCRIPTION

This specification describes computing systems including compute and memory, implemented by one or more circuit packages with photonic interconnects, which achieve reduced power consumption and/or increased processing speed as a result of the data-movement-related technologies described in this specification. In particular, power consumed for data movement is reduced by increasing data locality in each circuit package and reducing energy losses when data movement is needed compared to conventional computer systems. Power-efficient data movement, in turn, can be accomplished by moving data over small distances in the electronic domain, while leveraging photonic channels for data movement in scenarios where the resistance in the electronic domain and/or the speed at which the data can move in the electronic domain leads to bandwidth limitations. Thus, in some examples, each circuit package includes an electronic integrated circuit (EIC) that includes multiple compute nodes that are connected by bidirectional photonic channels, e.g., implemented in a PIC in a separate layer or chip of the package, into a hybrid, electronic-photonic (also referred to as an electro-photonic) network-on-chip (NoC). Multiple such NoCs may be connected, by inter-chip bidirectional photonic channels, e.g., channels implemented over optical fibers, between respective circuit packages, into a larger electro-photonic network, to scale the computing system to arbitrary size without incurring significant power or speed losses.

While the described computing systems and their various novel aspects are generally applicable to a wide range of processing tasks, they are particularly suited to implementing machine learning (ML) models, in particular, artificial neural networks (ANNs). As applied to ANNs, a circuit package and system of interconnected circuit packages as described in this specification are also referred to as an “ML processor” and “ML accelerator,” respectively.

Neural networks are machine learning models that include one or more layers of artificial neurons that compute neuron output activations from weighted sums of a set of input activations. These computations correspond to Multiply-Accumulate (MAC) operations. For a given neural network, the flow of activations between nodes and layers is fixed. Further, once training of the neural network is complete, the neuron weights in the weighted summation, and any other parameters associated with computing the activations, are likewise fixed. Thus, a NoC lends itself to implementing a neural network by assigning neural nodes to compute nodes, pre-loading the fixed weights associated with the neural nodes into memory of the respective compute nodes and configuring data routing between the compute nodes based on the predetermined flow of data between the neural nodes. The weighted summation can be efficiently performed using a dot product engine, also called a “digital neural network (DNN)” due to its applicability to ANNs.

Reference will now be made in detail to implementations, examples of which are illustrated in the accompanying drawings. In the following detailed description, numerous specific details are set forth to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the implementations.

Several features are described hereafter that can each be used independently of one another or with any combination of other features. However, any individual feature may not address any of the problems discussed above or might only address one of the problems discussed above. Some of the problems discussed above might not be fully addressed by any of the features described herein. Although headings are provided, information related to a particular heading, but not found in the section having that heading, may also be found elsewhere in this description.

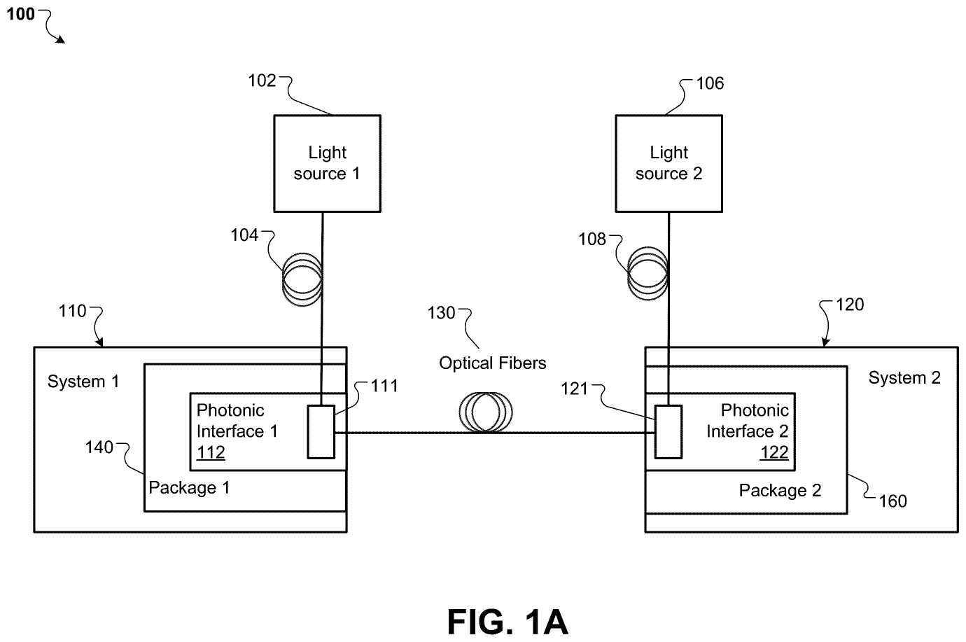

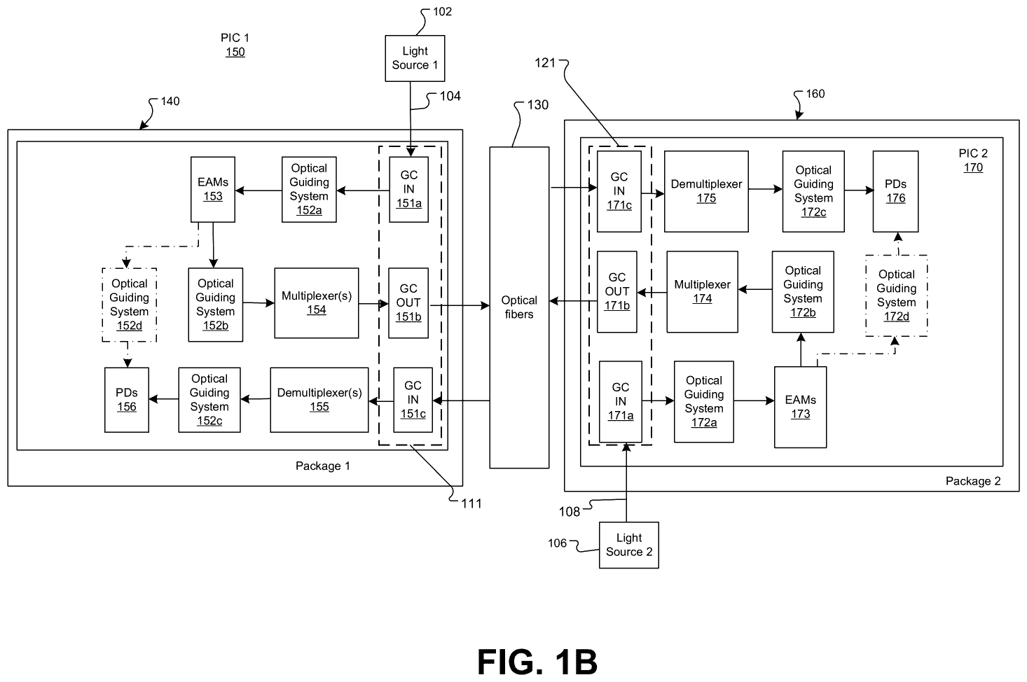

FIG. 1A is a diagram schematically illustrating an example system 100 including first and second systems 110, 120 configured to be connected with photonic interconnects for data communication, for example, with high bandwidth, high speed, and low latency and power.

In some implementations, the system 100 includes a server, a computing center, or a data center. The first system 110 can be a computing system including one or more computing elements, e.g., microprocessors (MPU), central processing units (CPUs), graphics processing units (GPUs), artificial intelligence (AI) accelerators, and/or digital application-specific integrated circuits (ASICs). The second system 120 can be a data storage system including one or more memory elements, e.g., NAND Flash memory, solid-state drive (SSD) memory, NOR Flash memory, complementary metal-oxide-semiconductor (CMOS) memory, thin film transistor-based memory, phase change memory (PCM), storage class memory (SCM), read-only memory (ROM), random-access memory (RAM), magneto-resistive RAM (MRAM), resistive RAM, static random access memory (SRAM), dynamic RAM (DRAM), synchronous dynamic random-access memory (SDRAM), Double Data Rate (DDR)-based DRAM, high bandwidth memory (HBM), and/or dual in-line memory module (DIMM) memory such as DDR-DIMM.

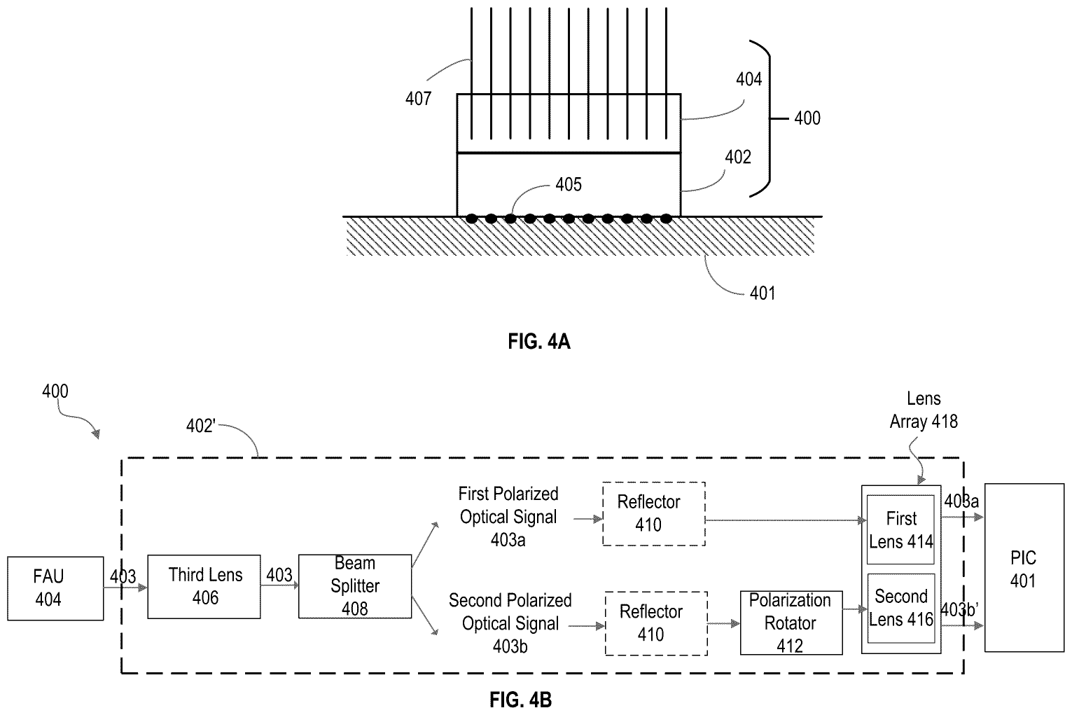

In some implementations, e.g., as illustrated with further details in FIG. 4D, the computing system can also include one or more memory elements (e.g., HBMs) that are in electrical connection with the one or more computing elements. The storage system can provide much larger storage capacity than the one or more memory elements in the computing system. In some examples, the storage system includes one or more HBM memory devices and one or more DDR memory devices such as DDR-based DRAMs or DDR-DIMMs. In such a way, compute and memory can be disaggregated, which allows computing elements and memory elements to be leveraged and scaled effectively to deliver high bandwidth and memory capacity while reducing latency and power consumption.

To ensure high data transmission with low latency between the first system 110 (e.g., the computing system) and the second system 120 (e.g., the storage system), photonic interconnect is implemented in the system 100. The first system 110 includes a first circuit package 140 that includes a first photonic interface 112, and the second system 120 includes a second circuit package 160 that includes a second photonic interface 122. The first circuit package 140 and the second circuit package 160 are configured to communicate with each other through one or more photonic channels between the first photonic interface 140 and the second photonic interface 160 that can be coupled to each other through optical fibers 130. The optical fibers 104 and 130 are attached to the first photonic interface 112 by a fiber array unit (FAU) assembly 111 and optical fibers 108 and 130 are attached to the second photonic interface 122 by a FAU assembly 121. The fiber array unit assemblies 111 and 121 position a respective fiber array unit with respect to photonic ports in the surface of a photonic integrated circuit (PIC) of the circuit packages to align optical fibers to transmit light between optical fibers and waveguides in the PICs.

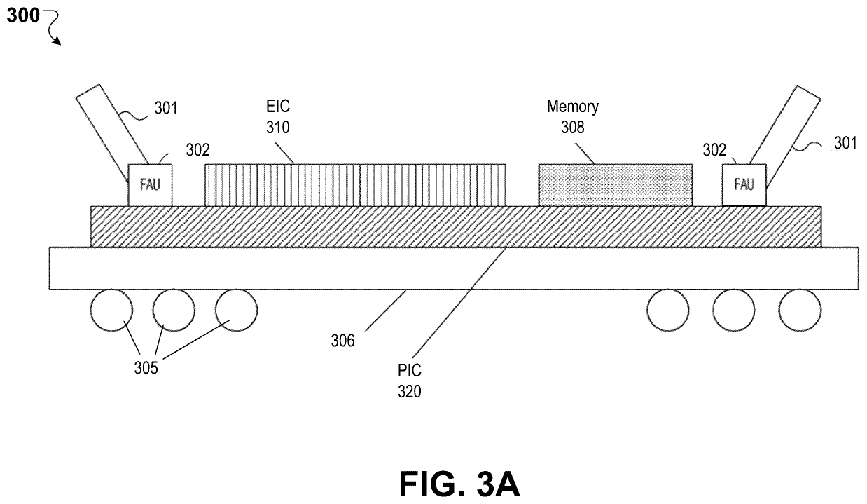

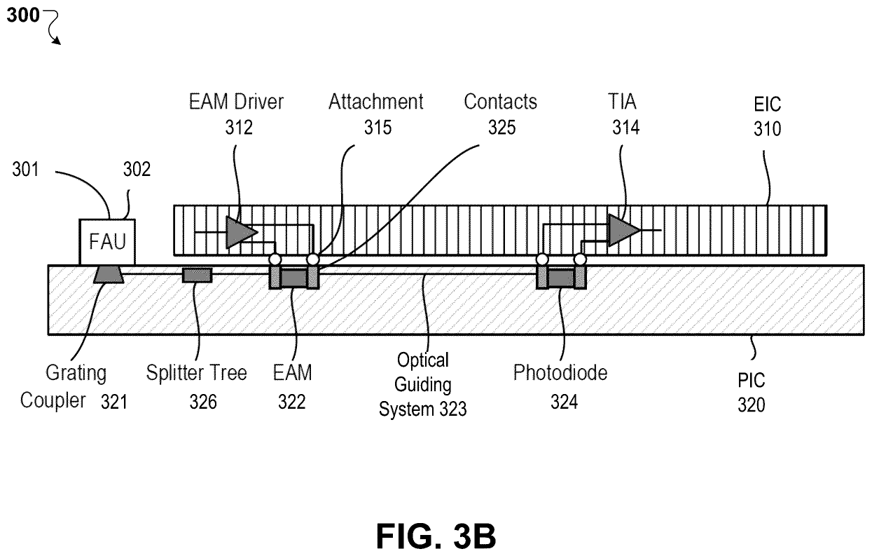

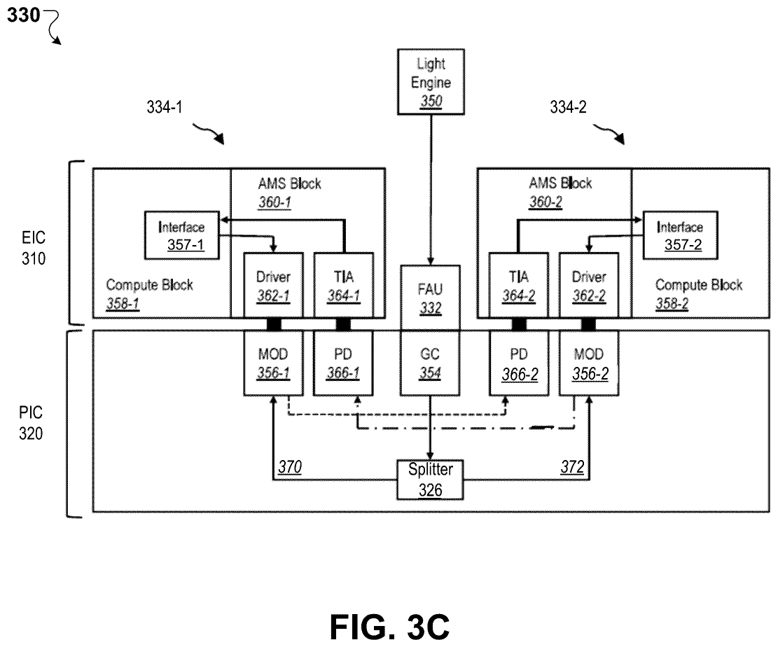

As discussed with further details below (e.g., FIGS. 3A-3C), in addition to a PIC, a circuit package (e.g., 140, 160) can include an electronic integrated circuit (EIC) such as a digital and mixed-signal application-specific integrated circuit (ASIC). The EIC and PIC can be formed in different layers of the circuit package, which can be referred to as “electronic circuit layer” and “photonic circuit layer,” respectively, one stacked above the other, for example, using copper pillars, bump attachments, or other means to create an electrical interconnect to transmit and receive messages, packets, and/or other data between the EIC and the PIC.

In some implementations, the EIC includes multiple compute nodes. The compute nodes can communicate with each other over one or more intra-chip bidirectional channels. The intra-chip bidirectional channels can include one or more bidirectional photonic channels, e.g., implemented with optical waveguides in the PIC, and/or one or more electronic channels, e.g., implemented in the circuitry of the EIC. The compute nodes may but need not in all examples be electronic circuits identical or at least substantially similar in design, and as shown, may form “tiles” of the same size arranged in a grid or any other arrangement suitable for performing the computations described herein. Each compute node in the EIC can include one or more circuit blocks serving as processing engines, e.g., a dot product engine, DNN, or a tensor engine. In examples, the compute node can have any combination of processing elements such as CPUs, GPUs, TPUs, and the like, and the DNN and tensor engine can also be included or omitted depending on the application. Each compute node can include a message router. The message routers interface with channels, e.g., electronic and/or photonic channels to facilitate data flow to and from the compute nodes. Further, the compute node can have a memory system, e.g., including level-one static random-access memory (L1SRAM) and level-two static random access memory (L2SRAM). In some implementations, a compute node includes a compute block which may include various processing, storage, and/or communication functions, and an Analog Mixed Signal (AMS) block that can include analog/mixed signal circuits for interfacing with the PIC, e.g., as illustrated with further details in FIGS. 3C. The compute block can include an interface for communicating with the AMS block, or more specifically, with the componentry of the AMS block.

A photonic integrated circuit (PIC) can include optical modulators and photodiodes, and an electronic integrated circuit (EIC) (e.g., an AMS block) can include modulator drivers and transimpedance amplifiers (TIAs). An optical modulator and a modulator driver can form an optical transmitter (TX), and a photodiode and a TIA can form an optical receiver (RX). In such a way, the circuit package can have at least one photonic transceiver (TX and RX) whose functionality resides partially in the PIC and/or partially in the EIC, which enables the photonic transceivers to send and receive data packets in the optical domain as modulated electromagnetic waves via photonic channels and/or as digital packets via electrical interconnections.

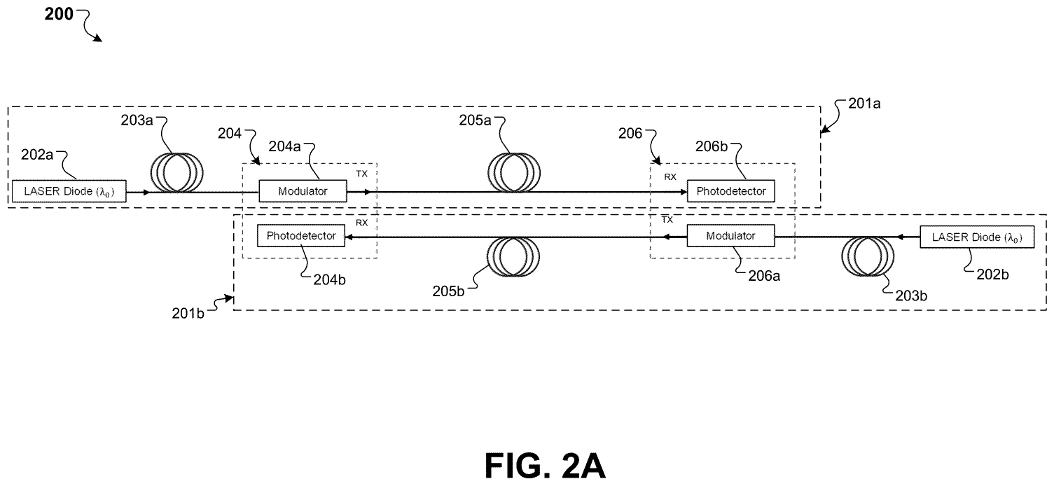

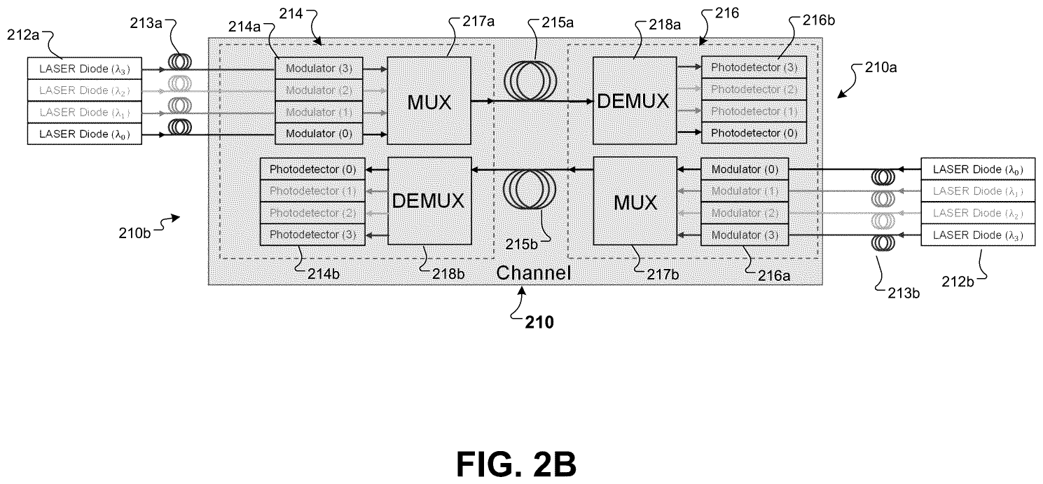

A photonic interface (e.g., 112, 122) can include one or more transmitters and/or one or more receivers. The one or more transmitters can be referred to as an electrical-to-optical (EO) interface, and the one or more receivers can be referred to as an optical-to-electrical (OE) interface. That is, a photonic interface (e.g., 112, 122) can include at least one of an EO interface or an OE interface. A transmitter in one photonic interface can connect with a receiver in another photonic interface to form a one-to-one unidirectional optical path (or an optical lane) (e.g., as illustrated with further details in FIG. 2A). Unidirectional optical paths form between the two photonic interfaces can be independent from each other, which can avoid crosstalk between different optical paths and/or avoid path length compensation between different optical paths (e.g., when light is continuous wave-CW light). When each of the photonic interfaces includes both EO interface and OE interface, the photonic interface can provide bi-directional optical paths for optical signals modulated with data (e.g., as illustrated with further details in FIG. 2A). A bi-directional optical path can include two unidirectional optical paths. As discussed with further details below (e.g., as illustrated with further details in FIG. 2B), a photonic channel can include one or more unidirectional optical paths or one or more bidirectional optical paths.

To provide a large number of optical paths for high bandwidth data communication between photonic interfaces (e.g., 112, 122), circuit packages (e.g., 140, 160), and/or systems (e.g., 110, 120), wavelength-division multiplexing (WDM) or Dense wavelength-division multiplexing (DWDM) technology can be utilized, such that light with multiple wavelengths can be utilized. In some examples, a photonic channel includes multiple bidirectional optical paths, and a number of the multiple bidirectional optical paths is identical to a number of the multiple wavelengths. A number of unidirectional optical paths can be twice of the number of multiple wavelengths.

As illustrated in FIG. 1A, each photonic interface 112, 122 (e.g., PIC) can receive input light from a corresponding light source 102, 106 via corresponding optical fibers 104, 108, respectively. Each light source 102, 106 can include multiple light elements each providing a corresponding single wavelength of the multiple wavelengths. A number of the multiple light elements can be the number of the multiple wavelengths or multiple times of the number of the multiple wavelengths. A light element can be a laser diode or a laser. In some examples, the light element is configured to emit continuous wave (CW) light. In some examples, the light element is configured to emit pulsed light. In some examples, the multiple wavelengths are in a range from 1,500 nm to 1,600 nm, e.g., in the band of the spectrum referred to as the C-band and/or L-band. In some examples, a difference between adjacent wavelengths is about 10 nm. Light transmitted in a unidirectional optical path can be polarized (e.g., with s polarization) in single mode. Optical fibers, e.g., 104, 108, 130, for transmission can be polarization-maintaining single-mode fibers (PM-SMFs) and/or non-polarization maintaining fibers.

In some implementations, a light source can be implemented into the PIC or implemented separately from the PIC either within or externally to the circuit package and coupled to the PIC by suitable optical couplers. For example, as illustrated in FIG. 1A, the light source can be integrated in a chip or a printed circuit board (PCB) coupled to the circuit package or the PIC, e.g., by suitable optical couplers.

An optical modulator can be an electro-absorption modulator (EAM), which is a semiconductor device that modulates the intensity of an optical signal by varying absorption of the optical signal as it traverses the modulator based on an electric voltage applied to the EAM. An operation of an EAM can be based on the Franz-Keldysh effect, e.g., a change in the absorption spectrum caused by an applied electric field, which changes the bandgap energy, and thus the photon energy of an absorption edge, but usually does not involve the excitation of carriers by the electric field. EAMs can be made in the form of a waveguide with electrodes for applying an electric field in a direction perpendicular to the modulated optical signal. In some examples, the EAM is implemented in a layer of germanium silicon, e.g., an epitaxially-grown layer of GeSi. Germanium can stoichiometrically constitute 90% or more of the GeSi material, e.g., 95% or more, 96% or more, 97% or more, 98% or more, or 99% or more.

FIG. 1B is a diagram schematically illustrating an example of the circuit packages 140 and 160. Each circuit package can include a corresponding PIC 150, 170. Each PIC can include a number of components, e.g., optical couplers such as grating couplers, optical guiding system, optical modulators such as EAMs, photodetectors such as photodiodes (PDs), optical multiplexer(s), and/or optical demultiplexer(s), that can be integrated in the PIC, e.g., as illustrated with further details in FIGS. 3B-3C. For illustration, the photodetectors and the photodiodes may be used interchangeably in the specification. These components can be implemented at least partially as waveguides.

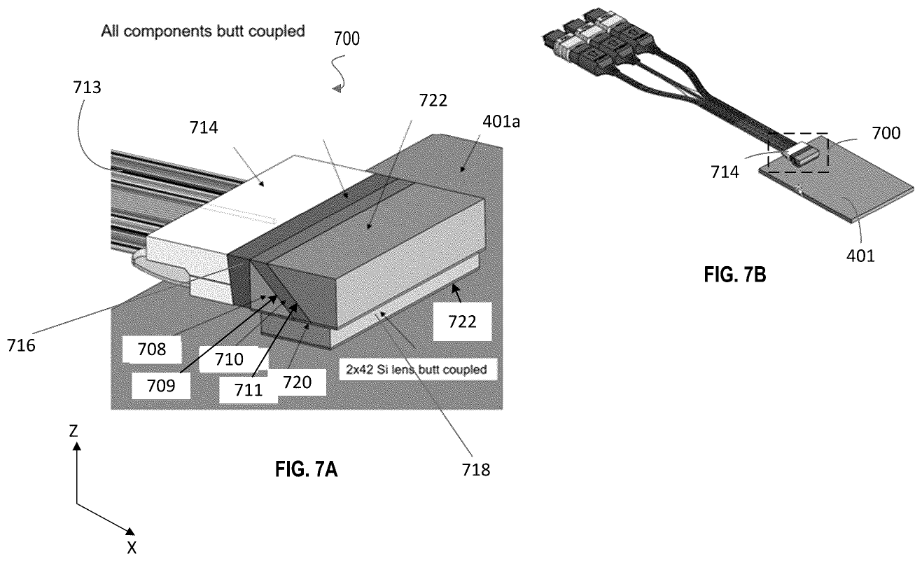

One or more photonic channels (unidirectional optical paths and/or bidirectional optical paths) can be formed between the circuit packages 140, 160, or the photonic interfaces 112, 122. For example, light from a first light source 102 can be coupled through optical fibers 104 and grating couplers 151a into a first PIC 150 of the first circuit package 140 and be further guided to optical modulators 153 such as EAMs through an optical guiding system 152a (e.g., as illustrated with further details in FIGS. 6A-6D). The optical modulators 153 can modulate the light with data by corresponding modulator drivers in a first EIC of the circuit package 140 to generate modulated light. When the light includes multiple light beams each with a single wavelength of multiple wavelengths, modulated light beams with single wavelengths from the optical modulators 153 can be guided (optionally through an optical guiding system 152b to a multiplexer 154. The multiplexer 154 can multiplex the multiple light beams into a multiplexed light beam (e.g., as illustrated with further details in FIG. 2E and 7B). The multiplexed light beam can be coupled out of the first PIC 150 through grating couplers 151b into the optical fibers 130 and then to the second circuit package 160. The multiplexed light beam can be coupled into a second PIC 170 in the second circuit package 160 through grating couplers 171c into a demultiplexer 175. The demultiplexer 175 can demultiplex the multiplexed light beam into multiple light portions each with a corresponding single wavelength (e.g., as illustrated with further details in FIGS. 2E and 7C). The multiple light portions each with the corresponding single wavelength can be guided (optionally through an optical guiding system 172c) to photodiodes 176. The photodiodes 176 can convert detected light into electrical data that can be transmitted to corresponding TIAs in the second EIC of the second circuit package 160. In such a way, one or more inter-chip unidirectional optical paths (or lanes) are formed from the optical modulators 153 in the first PIC 150 to the corresponding PDs 176 in the second PIC 170. Accordingly, one or more inter-package unidirectional data paths are formed from the modulator drivers in the first EIC to the TIAs in the second EIC.

In some implementations, one or more intra-chip unidirectional optical paths (or lanes) can be also formed from optical modulators to corresponding PDs in a same PIC, and accordingly, one or more intra-package unidirectional data paths can be also formed in a same circuit package, e.g., as illustrated in FIG. 1B and illustrated with further details in FIG. 3E.

In some implementations, as shown in FIG. 1B, the first PIC 150 can include a further optical guiding system 152d, e.g., channel waveguides, that can be coupled with one or more EAMs 153 to one or more corresponding PDs 156. Each of the one or more EAM 153 can modulate light with a single wavelength with data from a corresponding modulator driver in a corresponding EIC stacked with the PIC 150 in the same first circuit package 140 and transmit the modulated light through a corresponding channel waveguide of the optical guiding system 152d to a corresponding PD 156 of the one or more corresponding PDs 156 in the same PIC 150. The corresponding PD 156 can convert detected light into electrical data that can be electrically transmitted to a corresponding TIA in the corresponding EIC of the first circuit package 140. Thus, an intra-chip unidirectional optical path (or lane) is formed from the EAM 153 to the corresponding PD 156 in the first PIC 150, and accordingly, an intra-package unidirectional data path is formed from the corresponding modulator driver in the corresponding EIC through the EAM 153, the corresponding channel waveguide in the optical guiding system 152d, the corresponding PD 156 to the corresponding TIA in the corresponding EIC of the first circuit package 140.

Similarly, light from a second light source 106 can be coupled through optical fibers 108 and grating couplers 171a into the second PIC 170 of the second circuit package 160 and be further guided to optical modulators 173 such as EAMs through an optical guiding system 172a. The optical modulators 173 modulates the light with data by corresponding modulator drivers in the second EIC of the second circuit package 160 to generate modulated light. When the light includes multiple light beams each with a single wavelength of multiple wavelengths, modulated light beams with single wavelengths from the optical modulators 173 can be guided (optionally through an optical guiding system 172b to a multiplexer 174. The multiplexer 174 can multiplex the multiple light beams into a multiplexed light beam. The multiplexed light beam can be coupled out of the second PIC 170 through grating couplers 171b into the optical fibers 130 and then to the first circuit package 140. The multiplexed light beam can be coupled into the first PIC 150 in the first circuit package 140 through grating couplers 151c into a demultiplexer 155. The demultiplexer 155 can demultiplex the multiplexed light beam into multiple light portions each with a corresponding single wavelength. The multiple light portions each with the corresponding single wavelength can be guided (optionally through an optical guiding system 152c) to photodiodes 156. The photodiodes 156 can convert detected light into electrical data that can be transmitted to corresponding TIAs in the EIC of the first circuit package 140. In such a way, one or more unidirectional optical paths (or lanes) are formed from the optical modulators 173 in the second PIC 170 to the corresponding PDs 156 in the first PIC 150. Accordingly, one or more unidirectional data paths are formed from the modulator drivers in the second EIC to the TIAs in the first EIC.

In some implementations, as shown in FIG. 1B, the second PIC 170 can include a further optical guiding system 172d, e.g., channel waveguides, that can be coupled with one or more EAMs 173 to one or more corresponding PDs 176 in the second PIC 170. Each of the one or more EAM 173 can modulate light with a single wavelength with data from a corresponding modulator driver in a corresponding EIC stacked with the second PIC 170 in the same second circuit package 160 and transmit the modulated light through a corresponding channel waveguide of the optical guiding system 172d to a corresponding PD 176 of the one or more corresponding PDs 176 in the same second PIC 170. The corresponding PD 176 can convert detected light into electrical data that can be electrically transmitted to a corresponding TIA in the corresponding EIC in the second circuit package 160. Thus, an intra-chip unidirectional optical path (or lane) is formed from the EAM 173 to the corresponding PD 176 in the second PIC 170. Accordingly, an intra-package unidirectional data path is formed from the corresponding modulator driver in the corresponding EIC through the EAM 173, the corresponding channel waveguide in the optical guiding system 172d, the corresponding PD 176 to the corresponding TIA in the corresponding EIC of the second circuit package 160.

In some implementations, the grating couplers 151a, 151b, 151c in the first PIC 150 can be arranged in an array, that can be coupled (in and out) with the optical fibers 130, 104 together using a first fiber array unit (FAU) assembly (e.g., as illustrated with further details in FIGS. 3A-3B) or any other suitable coupling method (e.g., using V grooves for edge-coupled fibers). Similarly, the grating couplers 171a, 171b, 171c in the second PIC 170 can be arranged in an array, that can be coupled (in and out) with the optical fibers 130, 106 together using a second FAU assembly or any other suitable coupling method (e.g., using V grooves for edge-coupled fibers).

In some implementations, the optical guiding systems 152a, 152b, and 152c in the first PIC 150 can be configured such that light can be guided in or out from corresponding components in the first PIC 150 in an ordered, efficient way and in a miniaturized area. For example, optical modulators 153 and PDs 156 for each photonic channel are positioned in a same corresponding channel area, and light beams with corresponding single wavelengths can be guided as two groups respectively to the optical modulators 153 and the PDs 156 in the corresponding channel area. Channel areas for different photonic channels are arranged adjacent to each other. The multiplexers 154 and the demultiplexers 156 are arranged further from the channel areas and closer to the grating couplers 151a, 151b, 151c, and can be arranged parallel to one another. A multiplexer 154 and a demultiplexer 156 for a same photonic channel can be arranged adjacent to each other. In such a way, light from the optical modulators 153 to the multiplexer 154 and light from the demultiplexer 156 to the PDs 156 can be guided in corresponding waveguides adjacent to each other between a corresponding channel area and an area close to the grating couplers. Similarly, the optical guiding systems 172a, 172b, and 172c in the second PIC 170 can be configured such that light can be guided in or out from corresponding components in the second PIC 170 in an ordered, efficient way and in a miniaturized area.

FIG. 2A is a diagram illustrating an example bi-directional photonic channel 200 for light with a single wavelength (e.g., λ₀). The bi-directional photonic channel 200 includes two unidirectional optical paths (or lanes) 201a, 202b along opposite directions.

In a first optical path 201a, first light with the single wavelength λ₀ from a first light source such as a laser diode 202a is coupled through an optical fiber 203a (e.g., the optical fiber 104 or 108 of FIGS. 1A-1B) to a first optical modulator 204a (e.g., the optical modulator 153 or 173 of FIG. 1B) of a first transmitter. The first optical modulator 204a modulates the first light with data by a corresponding first modulator driver to provide modulated first light. The modulated first light is transmitted through a first optical fiber 205a (e.g., the optical fiber 130 of FIGS. 1A-1B) to a first photodetector 206b of a first receiver (e.g., the PD 176 or 156 of FIG. 1B). The first photodetector 206b can be connected to a corresponding first TIA. Thus, the first optical path 201a is formed from the optical modulator 204a to the first photodetector 206b.

In a second optical path 201b, second light with the single wavelength λ₀ from a second light source such as a laser diode 202b is coupled through an optical fiber 203b (e.g., the optical fiber 104 or 108 of FIGS. 1A-1B) to a second optical modulator 206a (e.g., the optical modulator 153 or 173 of FIG. 1B) of a second transmitter. The second optical modulator 206a modulates the second light with data by a corresponding second modulator driver to provide modulated second light. The modulated second light is transmitted through a second optical fiber 205b (e.g., the optical fiber 130 of FIGS. 1A-1B) to a second photodetector 204b of a second receiver (e.g., the PD 176 or 156 of FIG. 1B). The second photodetector 204b can be connected to a corresponding second TIA. Thus, the second optical path 201b is formed from the second optical modulator 206a to the second photodetector 204b.

As discussed above and below, the first optical modulator 204a and the second photodetector 204b can be integrated in a first PIC 204 (e.g., the PIC 150 or 170 of FIG. 1B) or in a first photonic interface (e.g., the photonic interface 112 or 122 of FIG. 1A) and be connected to the first modulator driver and the second TIA that can be integrated in a corresponding first EIC. The second optical modulator 206a and the first photodetector 206b can be integrated in a second PIC 206 (e.g., the PIC 150 or 170 of FIG. 1B) or in a second photonic interface (e.g., the photonic interface 112 or 122 of FIG. 1A) and be connected to the second modulator driver and the first TIA that can be integrated in a corresponding second EIC.

FIG. 2B is a diagram illustrating an example bi-directional photonic channel 210 for light with multiple wavelengths using wavelength-division multiplexing (WDM) technology. The bi-directional photonic channel 200 includes multiple bidirectional optical paths each with a corresponding single wavelength, or multiple pairs of unidirectional optical paths (or lanes) each with a corresponding single wavelength along opposite directions. For illustration, four wavelengths, e.g., λ₀, λ₁, λ₂, λ₃, are described in the present disclosure. It is understood that a larger or smaller number of wavelengths can be also implemented.

A first circuit 214 in a first PIC (e.g., the PIC 150 or 170 of FIG. 1B) can include multiple modulators 214a (e.g., the optical modulators 153 or 173 of FIG. 1B) and multiple photodetectors 214b (e.g., the PDs 156 or 176 of FIG. 1B). The first circuit 214 can also include an optical multiplexer 217a (e.g., the multiplexer 154 or 174 of FIG. 1B) and an optical demultiplexer 218b (e.g., the demultiplexer 155 or 175 of FIG. 1B). A second circuit 216 in a second PIC (e.g., the PIC 150 or 170 of FIG. 1B) can include multiple modulators 216a (e.g., the optical modulators 153 or 173 of FIG. 1B) and multiple photodetectors 216b (e.g., the PDs 156 or 176 of FIG. 1B). The second circuit 216 can also include an optical multiplexer 217b (e.g., the multiplexer 154 or 174 of FIG. 1B) and an optical demultiplexer 218a (e.g., the demultiplexer 155 or 175 of FIG. 1B).

Each optical modulator 214a in the first circuit 214 is configured to receive a light beam with a corresponding single wavelength (e.g., λ₀, λ₁, λ₂, or λ₃) from a corresponding laser diode 212a through a corresponding optical fiber 213a. The optical multiplexer 217a in the first circuit 214 multiplexes the multiple light beams from the multiple optical modulators 214a to obtain a multiplexed light beam that can be transmitted through an optical fiber 215a to the corresponding demultiplexer 218a in the second PIC 216. The demultiplexer 218a demultiplexes the multiplexed light beam into multiple light portions each with a corresponding single wavelength to corresponding photodetectors 216b (e.g., λ₀, λ₁, λ₂, or λ₃). Thus, a first group 210a of unidirectional optical paths with the multiple wavelengths is formed between the first circuit 214 and the second circuit 216.

Similarly, in the second PIC 216, each optical modulator 216a in the second circuit 216 is configured to receive a light beam with a corresponding single wavelength (e.g., λ₀, λ₁, λ₂, or λ₃) from a corresponding laser diode 212b through a corresponding optical fiber 213b. The optical multiplexer 217b in the second circuit 216 multiplexes the multiple light beams from the multiple optical modulators 216a to obtain a multiplexed light beam that can be transmitted through an optical fiber 215b to the corresponding demultiplexer 218b in the first circuit 214. The demultiplexer 218b demultiplexes the multiplexed light beam into multiple light portions each with a corresponding single wavelength to corresponding photodetectors 214b (e.g., λ₀, λ₁, λ₂, or λ₃). Thus, a second group 210b of unidirectional optical paths with the multiple wavelengths is formed between the first circuit 214 and the second circuit 216.

In some examples, the number of wavelengths is 4. For a photonic channel 210, there can include 4 optical modulators, 4 photodetectors, one optical multiplexer, and one optical demultiplexer in each of the first circuit 214 and the second circuit 216.

FIG. 3A is a diagram illustrating an example structural circuit package 300 (e.g., the circuit package 140 or 160 of FIGS. 1A-1B). In this example, an EIC 310 and a PIC 320 (e.g., the PIC 150 or 170 of FIG. 1B) are formed in separate semiconductor chips, e.g., silicon chips, although other semiconductor materials may be used. The PIC 320 can be disposed directly on a substrate 306, shown with solder bumps 305, for subsequent mounting to a printed circuit board (PCB). The EIC 310 and FAU assemblies 302 that connect the PIC 320 to external waveguides 301, e.g., optical fibers, are disposed on top of and optically connected to the PIC 320. The EIC 310 can include ASIC that can be a 5 nm system-on-chip (SOC). Optionally, the circuit package 300 can further include an on-chip memory 308 positioned on top of the PIC 320 adjacent to the EIC 310.

The depicted structure of the circuit package 300 is merely one of several possible ways to assemble and package the various components. In some examples, some or all of the EIC 310 is disposed on the substrate. In some examples, some or all of the PIC 320 is placed on top of the EIC 310. In some examples, it is also possible to create the EIC 310 and PIC 320 in different layers of a single semiconductor chip. In some examples, the photonic circuit layer includes or is made of multiple PICs 320 in multiple sub-layers. Multiple layers of PICs 320, or a multi-layer PIC 320, may help to reduce waveguide crossings. Moreover, the structure may be modified to included multiple EICs 301 connected to a single PIC 320. For example, the multiple EICs 301 may be connected to each other by photonic channels in the PIC 320.

In some implementations, the EICs and PICs can be manufactured using standard wafer fabrication processes. Further, in some examples, heterogeneous material platforms and integration processes are used. For example, various active photonic components, e.g., the laser light sources and/or optical modulators and photodetectors used in the photonic channels, may be implemented using group III-V semiconductor components.

The laser light source(s) can be implemented either in the circuit package 300 or externally. When implemented externally, a connection to the circuit package 300 may be made optically using a grating coupler in the PIC 320 underneath an FAU assembly 302 as shown and/or using an edge coupler. In some cases, lasers are implemented in the circuit package 300 by using an interposer containing several lasers that can be co-packaged and edge-coupled with the PIC 320. In some cases, the lasers are integrated directly into the PIC 320 using heterogenous or homogenous integration. Homogenous integration allows lasers to be directly implemented in the silicon substrate in which the waveguides of the PIC 320 are formed, and allows for lasers of different materials, such as indium phosphide (InP), and architectures such as quantum dot lasers. Heterogenous assembly of lasers on the PIC 320 allows for group III-V semiconductors or other materials to be precision-attached onto the PIC 320 and optically coupled to a waveguide implemented on the PIC 320.

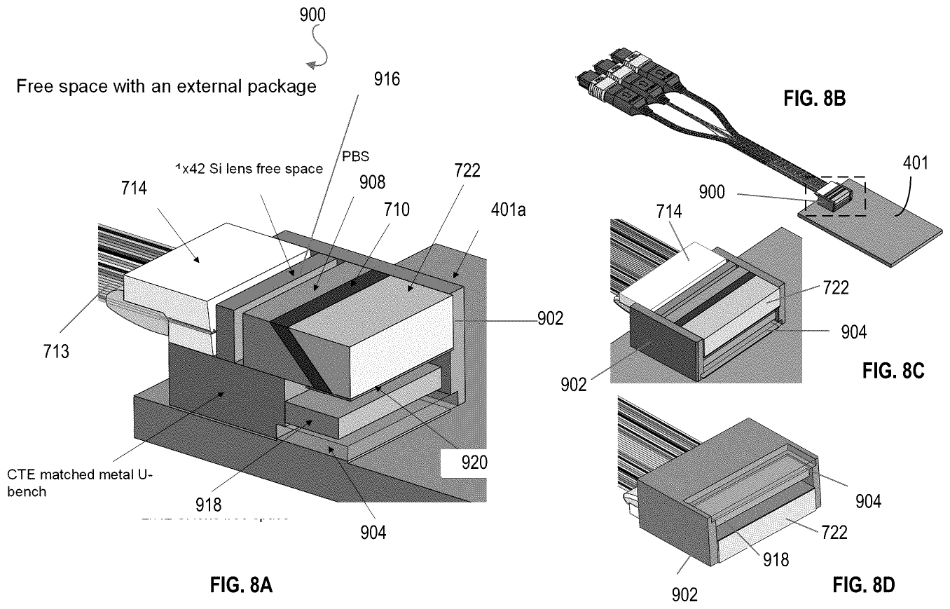

Light from fibers or to fibers can be coupled into and out of a PIC using a number of different ways. In some examples, as illustrated in FIGS. 3A-3B, and further in FIGS. 8A-8D, multiple fibers 301 (e.g., in an array) and grating couplers in the PIC 320 can be coupled by a FAU assembly 302 which a FAU attaches to a surface of the PIC (e.g., the same surface as the EIC, as illustrated). In some examples, the PIC can include edge couplers with V-grooves and the fibers can be positioned on the V-grooves and coupled with their edges to waveguides in the PIC. In some examples, light is coupled in or out from a side of the PIC 320 or in or out from a top surface of the PIC 320.

In some implementations, multiple circuit packages 300 may be interconnected to result in a single system providing a large electro-photonic network, e.g., by connecting several chip-level electro-photonic networks. Multiple circuit packages configured as ML processors may be interconnected to form a larger ML accelerator. For example, the photonic channels within the several circuit packages or ML processors, the optical connections, the laser light sources, the passive optical components, and the external optical fibers on the PCB, may be utilized in various combinations and configurations along with other photonic elements to form the photonic fabric of a multi-package system or multi-ML-processor accelerator.

FIG. 3B is a diagram schematically illustrating the example circuit package 300 with more details. The PIC 320 can be included in an interposer, and the EIC 310 can be stacked on the PIC 320. As illustrated in FIG. 3B, the PIC 320 can include an optical guiding system 323 (e.g., made of channel waveguides). The optical guiding system 323 can include one or more grating couplers 321 attached to the FAU assembly 302, one or more splitter trees 326, and one or more optical modulators (e.g., EAMs) 322 having contacts 325 with one or more modulator drivers (e.g., EAM drivers) 312 in the EIC 310 via attachments 315. In various embodiments, the attachment 315 is a pillar attachment, such as a 50 um pillar. The PIC 320 can also include one or more photodiodes 324 that can be electronically connected to one or more corresponding trans-impedance amplifiers (TIAs) 314 in the EIC 310, e.g., by the attachment 315.

In various embodiments, in a design like the circuit package 300, an EIC is directly coupled to a PIC, such as shown in FIG. 3B. While FIG. 3B shows a particular configuration of a direct coupling between electronic and photonic elements, many other examples are possible. For example, while a copper pillar attachment connects an EAM driver to an EAM as well as connects a photodiode to a TIA, other embodiments for direct coupling (chip-to-chip packaging) can be used.

In various embodiments, the EAM is an optical modulation element that enables light to pass between a cathode and an anode. Additionally, the EAM provides thermal stability at over 30 degrees Centigrade and enables the PIC 320 to be packaged directly with one or more processors of the EIC 310 and/or memory chips. The EAM can provide optical connectivity both within a chip and chip-to-chip. In some examples, the EAM can be about 50 microns in size and/or operate at data rates between 50-115 Gbps, at less than 1.0 volt of power (but up to 2.0volts).

FIG. 3C illustrates an example of a circuit package 330 implementing an intra-chip bidirectional photonic channel between a first compute node 334-1 and a second compute node 334-2. The circuit package 330 can be same as or similar to the circuit package 140 or 160 of FIGS. 1A-1B or 300 of FIGS. 3A-3B. The circuit package 330 can include various electronic and optical components implemented across an EIC 310 and a PIC 320.

The circuit package 330 includes two compute nodes 334-1 and 334-2, collectively, compute nodes 334, which each include a respective compute block 358-1 and 358-2 which may include various processing, storage, and/or communication functions. The compute nodes 334 each include an Analog Mixed Signal (AMS) block 360-1 and 360-2, collectively AMS blocks 360, that includes analog/mixed signal circuits for interfacing with the PIC 320. The compute blocks 358 each include an interface 357-1 and 357-2, collectively interfaces 357, for communicating with the AMS blocks 360, or more specifically, with the componentry of the AMS blocks 360. The AMS blocks 360 each include a modulator driver 362-1 and 362-2, collectively drivers 362, and each include a transimpedance amplifier (TIA) 364-1 and 364-2, collectively TIAs 364. The PIC 320 includes a pair of modulators 356-1 and 356-2 and a pair of photodetectors 366-1 and 366-2. The PIC 320 also includes a grating coupler 354 or other optical interface (OI) configured to receive and pass on light to one or more components and an optical splitter 326.

A light engine 350 can provide light as an optical carrier signal for communication between the first compute node 334-1 and second compute node 334-2. The light engine 350 provides the carrier signal to a FAU 332 of the circuit package 330, such as through an optical fiber. The FAU 332 is optically coupled to the grating coupler 354 which directs the optical carrier signal on to other components of the circuit package 330. The splitter 326 receives the optical carrier signal from the grating coupler 354 and splits the optical signal along two optical paths 370 and 372. More generally, the splitter 326 may distribute the optical carrier signal over any number of photonic paths. The optical paths 370 and 372 may be implemented as any suitable optical transmission medium and may include a mixture of waveguides and optical fibers, or any other suitable transmission medium. In the present example, the optical paths 370 and 372 can be implemented as waveguides in the PIC 320.

The optical paths 370 and 372 pass from the splitter 326 to the optical modulators 356-1 and 356-2, respectively. Each optical modulator modulates the optical carrier signal it receives from the splitter 326 based on information from its respective optical driver 362-1 and 362-2 and transmits the modulated signal along the respective optical path. A first photodetector 366-1 receives the modulated signal from the optical path, e.g., from the associated modulator 356-2. As depicted, the optical path from modulator 356-1 connects to photodetector 366-2 and the optical path from modulator 356-2 connects to photodetector 266-1. The photodetectors 366-1, 366-2 convert the received modulated signal into respective electrical signal and pass the electrical signals to a transimpedance amplifier 364-1, 364-2 through which the compute nodes 334-1 and 334-2 receive the information encoded in the signals. In this way, communication occurs between the compute nodes through the various components just described. Accordingly, the PIC 320 described here includes an intra-chip bidirectional photonic channel, including two unidirectional photonic links for communicating both to and from each compute node. Here, the first unidirectional photonic link is defined by the modulator driver 362-1, the optical modulator 356-1, the optical path 370, the photodiode 366-2, and the transimpedance amplifier 364-2. Similarly, the second unidirectional link is defined by the modulator driver 362-2, the optical modulator 356-2, the optical path 370, the photodiode 366-1, and the transimpedance amplifier 364-1. The first and second unidirectional links operate in opposite directions. Additionally, one or more of the compute nodes 334 may include one or more serializers and/or deserializers for communicating signals between the compute nodes 334. In this way, the two unidirectional photonic links form the intra-chip bidirectional photonic channel.

Referring to FIG. 4A, an example FAU assembly 400 includes a FAU 404 that is attached to an optical assembly 402 that contains mounting components to align the ends of optical fibers 407 with photonic ports 405 at a surface of a PIC 401. The optical assembly also includes optical components to focus light emitted from fibers 407 on the ports 405 and/or focus light emitted from the ports 405 onto the ends of fibers 407.

One type of optical fiber useful for such applications is polarization-maintaining optical fiber (PMF), which preserves the polarization state of light as it propagates through the fiber. It can be useful in applications where maintaining a specific polarization orientation of light is advantageous, for example, when it is coupled with a polarizing grating coupler where the efficiency of light coupling may vary based on the orientation of the incoming optical signal's polarization. A polarized optical signal can be s-polarized, i.e., with electric field vector perpendicular (transverse) to the plane of incidence, or p-polarized, i.e., with electric field vector parallel to the plane of incidence.

Another type of optical fibers is non-polarization-maintaining optical fiber. Unlike PMFs, non-polarization-maintaining optical fibers does not maintain polarization as light propagates through the fiber. For example, a non-polarization-maintaining optical fiber can change the polarization state (predictably or randomly) and/or allow polarized light to depolarize as it propagates.

Typically, photonic integrated circuits (PICs) transmit data using polarized light. Accordingly, PMFs are sometimes used to maintain the polarization state of the light as it propagates between PICs. However, polarization maintaining fibers are generally more expensive than conventional, non-polarization maintaining fiber.

In some implementations, the systems described in this specification can take advantage of conventional, non-polarization maintaining fiber for delivery of light to and from a PIC. Such systems can include an FAU assembly for surface coupling an unpolarized or arbitrarily polarized optical signal into a PIC. The assembly splits the optical signal from an optical fiber into two optical signals having orthogonal polarization states and couples the two optical signals into a pair of photonic ports in the PIC.

FIG. 4B is a schematic view of an example FAU assembly 400 to couple an unpolarized optical signal from an optical fiber into a pair of waveguides in a photonic integrated circuit (PIC). The assembly 400 is composed of a FAU 404 and an optical assembly 402′ to deliver two polarized optical signals 103a and 103b′ from a single conventional optical fiber to the PIC 101. The optical assembly 402′ includes, in order from the FAU 404, a lens 406, a beam splitter 408, an optional reflector 410, a polarization rotator 412, and a lens array 418 that includes lenses 414 and 416. The optional reflector 410 can be a reflecting prism. The beam splitter 408 is a polarizing beam splitter (PBS). In some implementations, the polarization rotator 412 is a half-wave plate or a twisted nematic liquid crystal.

During operation, light 403 from the fiber diverges as it emerges from the FAU 404 and is collimated by the lens 406 before being incident on the beam splitter 408. The beam splitter 408 splits the incident light 403 into two beams, a first polarized optical signal 403a, and a second polarized optical signal 403b, which is orthogonally polarized to the first signal 403a. In some implementations, the first polarized optical signal 403a is s-polarized, and the second polarized optical signal 403b is p-polarized. In some implementations, the reflector 410 is arranged to fold the path of either or both the first polarized optical signal 103a or the second polarized optical signal 103b to direct it towards the surface of the PIC 401 (examples are described below).

The second polarized optical signal 403b is incident on the polarization rotator 412 which rotates the polarization state by 90°. As a result, the second polarized optical signal 403b emerging from the polarization rotator 412 has the same polarization state as the first signal 403a, e.g., both can be s-polarized when the rotator 412 transforms p-pol into s-pol. The lens 414 and the lens 416 respectively focus like-polarized light beams onto respective photonic ports, e.g., a grating coupler, at the surface of the PIC 401, through which each of the two light beams is coupled into a respective one of a pair of waveguides in the PIC 401.

In general, the FAU 404 has multiple channels, including one or more transmitter channels, one or more receiver channels, one or more power channels, and one or more alignment channels. For example, in certain cases, the FAU 404 has 42 total channels, including 16 channels for transmitters, 16 channels for receivers, 8 channels for power, i.e., channels that provide laser light for modulation into data signals, and 2 dummy channels, e.g., for alignment purpose.

In some implementations the assembly 400 has a horizontal configuration. In a horizontal configuration, the FAU 404 emits light parallel to the surface of the PIC 401 and reflectors in the optical assembly are used to fold the light path towards the photonic ports. Horizontal configurations can be more robust against external forces acting in the lateral direction, e.g., the first direction, compared to configurations where the fibers are arranged perpendicular to the PIC surface. In addition, a horizontal configuration may allow for a more compact system configuration along the vertical direction.

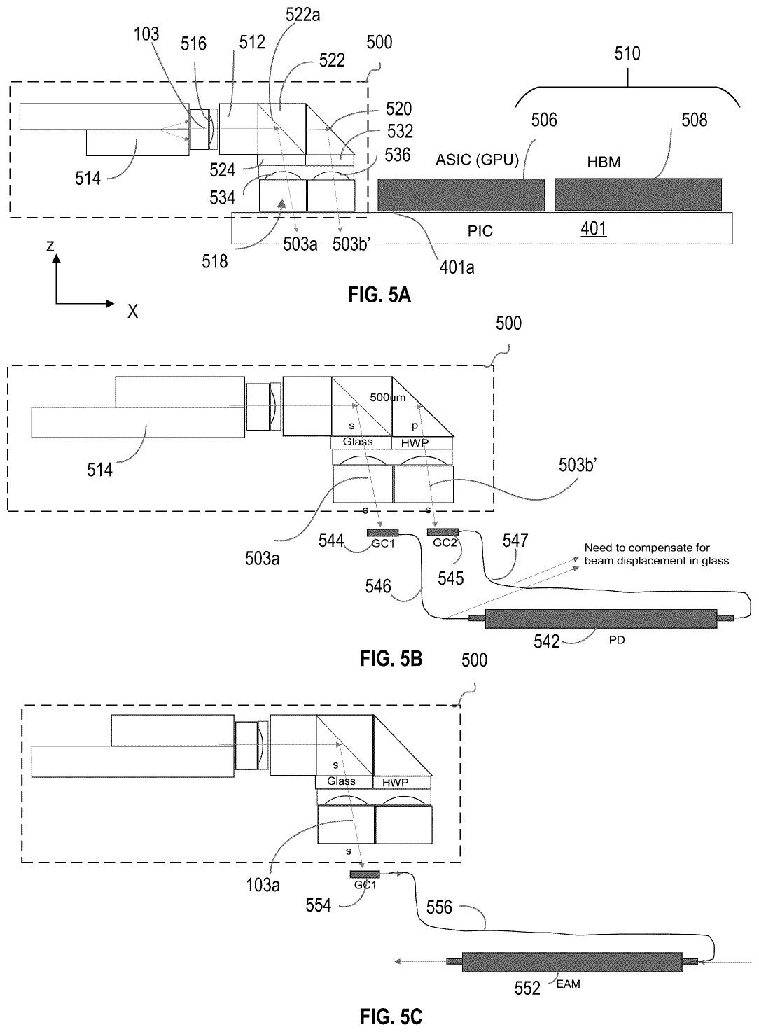

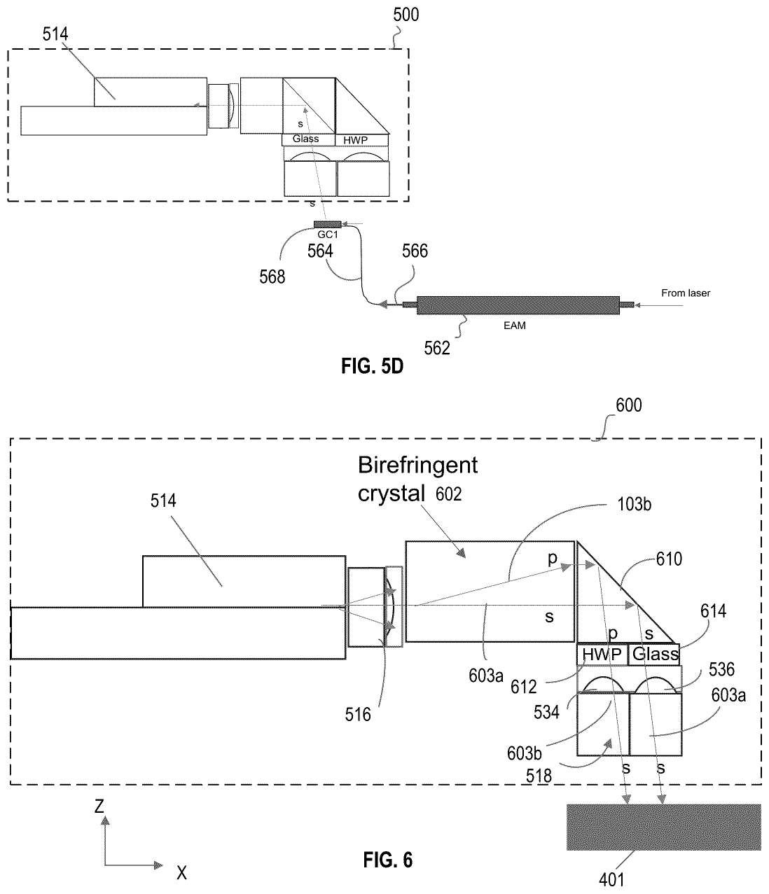

Referring to FIGS. 5A-5D, an example of a horizontally configured FAU assembly is assembly 500. In this example, assembly 500 is affixed (e.g., using an adhesive) to a surface 401a of the PIC 401 with an FAU 504 arranged to emit light in the x-direction parallel to the surface 401a. EICs 510, including an ASIC 506 and a HBM module 508, are also mounted on the surface 401a of the PIC.

The assembly 500 delivers two polarized optical signals 503a and 503b′ to the PIC 401 from a conventional optical fiber. The assembly 500 includes, in order along the light path, a FAU 514, a lens 516, a transparent (e.g., glass) spacer 512, a polarizing beam splitter (PBS) 522 with a polarizing interface 522a, a reflector 520 (e.g., a prism, e.g., with a reflective surface), a transparent spacer 524, a polarization rotator 532, and a lens array 518 that includes lenses 534 and 536.

The lens 516 collimates the light 103 emitted from a fiber in FAU 514 before the beam 103 is incident on the PBS 522. The spacer 512 provides an offset separating the lens 516 from the PBS 522.

The PBS 212 transmits p-polarized light through the interface 522a, while reflecting the orthogonal s-polarized light. The reflected beam, 103a propagates along a first path through the spacer 524 before being focused by the lens 534 onto a first photonic port on the surface 401a of the PIC 401. The second beam transmitted by the PBS 522 reflects from reflector 520 and passes through the polarization rotator 532. This rotator rotates the polarization state of the beam by 90°. As a result, the beam 503b′ emerging from the polarization rotator 112 has the same polarization state as beam 503a (s-pol). The lens 536 focuses the beam 503b′ onto a second photonic port adjacent the first port on the surface 401a. The photonic ports at the PIC surface 401a are separated by a distance corresponding to the difference in path lengths between the first and second beams. This distance can be relatively small, e.g., 1 mm or less, 0.8 mm or less, 0.5 mm or less, 0.4 mm or less, 0.25 mm or less, 0.2 mm or less, for example, about 0.1 mm.

In some implementations, the signals 503a and 503b′ can be delivered to a photodetector, e.g., a photodiode, in the PIC 401. For example, referring to FIG. 5B, the PIC 401 includes grating couplers 544 and 545 at the first and second photonic ports, respectively, that couple the beams 503 and 503b′ into respective waveguides 546 and 547 in the PIC. The waveguides 546 and 547 each couple light into opposite ends of a photodetector 542.

The grating couplers 544, 545 can have a periodic structure of grooves or ridges etched on into a layer or layers of the PIC 401 that also includes the waveguides. These periodic structures act as a diffraction grating and can efficiently couple light entering the PIC from the photonic port into the waveguides.

The waveguide 546 and 547 can have different optical path lengths, e.g., to compensate for the optical path length difference between the two beams due to the different paths in the assembly 500. The optical path length difference between the waveguides can be 1 mm or less, e.g., 0.8 mm or less, 0.5 mm or less, 0.4 mm or less, 0.25 mm or less, 0.2 mm or less, e.g., about 0.1 mm. In some implementations, the assembly 500 and waveguides 546, 547 are configured so that the two optical signals have the same frequency and net group delay when they reach the photodetector 542. The intensity of each signal can be the same or different.

In some examples, an optical assembly delivers light from a fiber in an FAU to a modulator in the PIC, which encodes data into the optical signal. Referring to FIG. 5C, the assembly 500 is arranged to couple the first s-polarized beam 503a into a port with a grating coupler 554 which couples the light into a waveguide 556 that directs the optical signal to the modulator 552. The modulator 552 modulates the optical signal and emits a modulated optical signal through the opposite end from which the optical signal entered.

The modulator 552 can be an electro-absorption modulator (EAM), which is a semiconductor device that modulates the intensity of an optical signal by varying absorption of the optical signal as it traverses the modulator 552 based on an applied electric voltage to the EAM. Generally, the principle of operation of an EAM is based on the Franz-Keldysh effect, i.e., a change in the absorption spectrum caused by an applied electric field, which changes the bandgap energy, and thus the photon energy of an absorption edge, but usually does not involve the excitation of carriers by the electric field. EAMs can be made in the form of a waveguide with electrodes for applying an electric field in a direction perpendicular to the modulated optical signal. In certain examples, the EAM is implemented in a layer of germanium silicon, e.g., an epitaxially-grown layer of GeSi.

While in the foregoing examples the assembly 500 is used to deliver light to the PIC 401, the assembly can also (or alternatively) be used to couple light out of the PIC and into a fiber. For example, FIG. 5D shows assembly 500 arranged for transmission of a signal modulated by a modulator 562 in the PIC into a fiber in the FAU 514. As illustrated, a signal of polarized light 566 from an EAM 562 is guided to a grating coupler 568 by the waveguide 564. The optical signal 566, in the present example, s-polarized, is reflected by the interface 522a of the PBS 522, and coupled into a fiber in the FAU 514.

In some implementations, the outcoupled signal can be delivered to the polarization rotator 532 and reflector 520, having its polarization state rotated before being coupled into the fiber.

In the prior examples, PBS 522 is composed of a pair of prisms that are bonded at the interface 522a with a coating at the interface to facilitate the polarized beam splitting. More generally, other beam splitters can be used. For example, FIG. 6 shows an example of an assembly that includes a birefringent crystal 602 in place of the PBS 522. The birefringent crystal 602 is an optically anisotropic material that has different refractive indices for light of different polarizations. Therefore, when light passes through the birefringent crystal 602, it splits into two orthogonally polarized beams 603a and 603b. In this example, both the s-polarized and p-polarized beams 603a, 603b emerge from the birefringent crystal 602 propagating in the forward direction, e.g., X direction, albeit displaced from each other. A reflector 610 reflects both beams towards the PIC 401 surface. The p-polarized light beam 603b is incident on a polarization rotator 612 (e.g., a half wave plate) which rotates the polarization state by 90°. As a result, the light emerging from the polarization rotator 612 is also s-polarized. Two s-polarized beams are then incident onto the surface of the PIC 401.

FIGS. 5A-6 show a single channel of example assemblies, i.e., the light path from a single fiber in the FAU. In general, a FAU includes multiple fibers arrayed together that collectively deliver light to and receive light from multiple channels in the PIC. Accordingly, optical assemblies for coupling this light between the FAU and the PIC will include multiple channels that align with respective pairs of ports on the PIC surface.

Referring to FIGS. 7A and 7B, an example of such an assembly 700 is shown in perspective view. Assembly 700 couples fibers 713 in a FAU 714 to the PIC 401. The assembly includes a lens array 708, a polarizing beam splitting (PBS) interface 709 formed between a wedge prism 708 and a plate 710. The plate 710 is attached to an end plate 722. An interface 720 between the plate 710 and the end plate 722 is a reflective interface which directs light transmitted through the PBS interface 709 towards the PIC 401. The assembly also includes a lens array 718 and a layer 720 between the lens array 718 and the bottom surface formed by the block composed of the wedge prism 708, the plate 710, and the end plate 722. The components of the assembly are cemented together and the assembly is adhered to the surface 401a of the PIC by a layer 724 of optical adhesive.

Generally, assembly 700 can be configured to couple any reasonable number, N, of fibers to a PIC. In some examples, the assembly can couple an array of 20 to 100 fibers (e.g., 40 fibers or more, 60 fibers or less). Generally, the lens array 708 includes a 1×N array of lenses and the array 718 includes a 2×N array of lenses, each aligned with a corresponding photonic port on the surface 401a.

In assembly 700, the PBS is butt coupled to the reflector, the reflector is butt coupled to the polarization rotator, and the polarization rotator is butt coupled to the lens array 718. Butt coupling can provide some advantages, including increasing coupling efficiency by aligning optical elements in direct contact and enhancing the transfer of optical power between them. It may also reduce the reflections at the interface and thus reduce signal loss. In addition, it allows for a compact design.

While the assembly 700 includes a number of optical components butt coupled together, examples can also include free space in the optical path. For example, referring to FIGS. 8A-8D, an assembly 900 includes several optical components that are spaced apart, providing air gaps in the optical path of the light. In particular, assembly 900 includes a prism 908, the plate 710, and the end plate 722 cemented together to form an integrated block containing the PBS and reflector. A lens array 916 is positioned between this block and the FAU 714 with air gaps in between the lens array and the FAU and between the lens array and the block. A polarization rotator/spacer layer 920 is bonded to the block on its lower surface and spaced apart from a lens array 918. A window 904 is arranged between the lens array 918 and the surface 401a of the PIC. A housing 902 (e.g., formed from a metal with similar thermomechanical properties of the optical components) provides a platform for mounting the optical components relative to each other and for bonding to the PIC surface 401a. Together with the window 904, the housing 902 provides a protective housing for the optical components of the assembly. The housing 902 can be made of a material including, but not limited to, aluminum, stainless steel, plastics, composites, or ceramics. The housing 902 can physically protect delicate optical components from external factors, provide isolation from the external environment, and reduce the entry of contaminants.

Configurations with free space between lenses and adjacent optical components can provide some advantages, such as greater alignment tolerance, reduced contamination risk, and greater flexibility for component interchangeability.

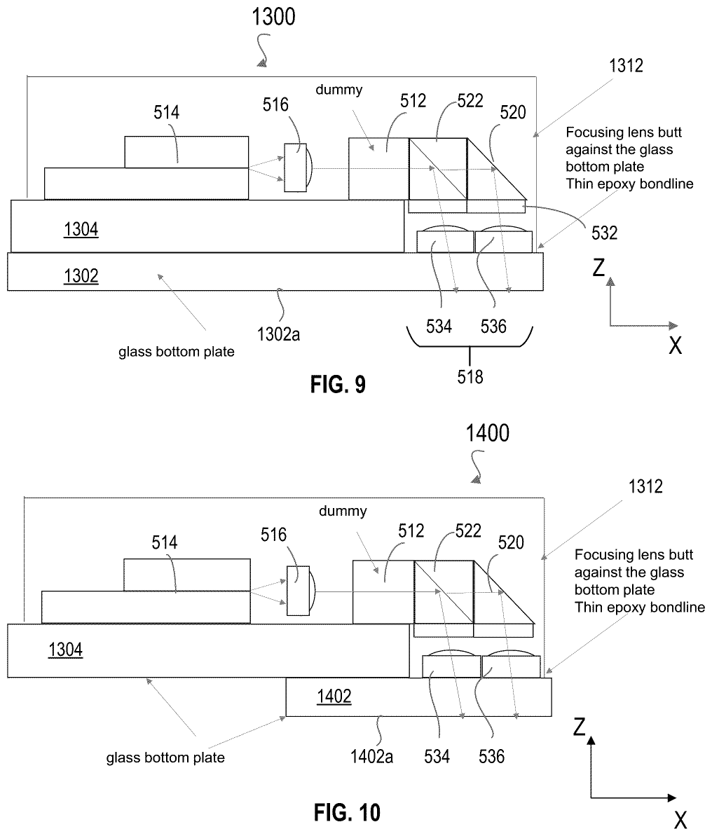

Other configurations are possible. For example, FIG. 9 shows an example assembly 1300 that includes a pair of glass substrates 1302 and 1304. The glass substrate 1302 directly supports the lens array 518 and the upper glass substrate 1304. A lid 1312 encloses the optical components against the glass substrate 1302. The upper substrate 1304 directly supports the FAU 514, lens 516 and a block formed from the spacer 512, PBS 522, reflector 520 and the spacer/polarization rotator 532. The block extends over the edge of the upper glass substrate 1304, positioning the PBS 522 and reflector 520 over the lens array 518. The bottom surface 1302a of the glass substrate 1302 can be attached to the top surface 401a of the PIC. The use of glass substrates in the assembly 1300 can improve robustness against external physical forces acting on the optical components.

In some examples, the glass substrate 1302 does not need to be co-extensive with the upper glass substrate 1304. For example, referring to FIG. 10 an assembly 1400 is the same as assembly 1300 except that the lower glass substrate 1402 overlaps with substrate 1304 on one edge only, i.e., it is shorter than the glass substrate 1304 in the X direction. In cases where the substrates are coextensive in the Y-direction, the glass substrate 1402 has a smaller area on its bottom surface 1402a compared with surface 1302a.

The smaller surface may allow for a more compact system configuration and an increased packaging density. It may also allow for a space-efficient design for the PIC 401 such that a more substantial portion of the PIC 401 can be dedicated to active devices.

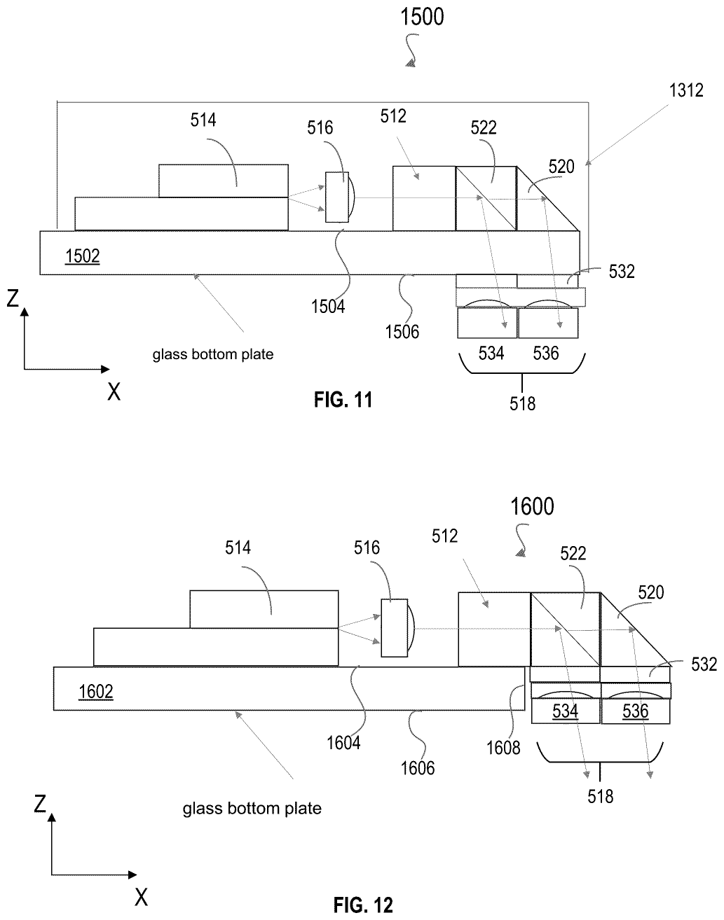

A further example assembly is assembly 1500 shown in FIG. 11, which includes a single glass substrate 1502. The FAU 514, the lens 516, the spacer 512, the beam splitter 522, and the reflector 520 are attached to a top surface 1504 of the glass substrate 1502. The polarization rotator 532 and the lens array 518 are attached to the bottom surface 1506 of the glass substrate 1502. The glass substrate 1502 provides structural support for the optical components attached to it. Reducing the number of glass substrates to just one also lowers manufacturing costs.

FIG. 12 shows yet another example assembly 1600 which includes a glass substrate 1602 that partially supports the block composed of the spacer 512, PBS 522, and reflector 522 on top surface 1604. The lens array 518 is arranged adjacent to a side surface 1608 of the glass substrate 1602 rather than its bottom surface 1606.

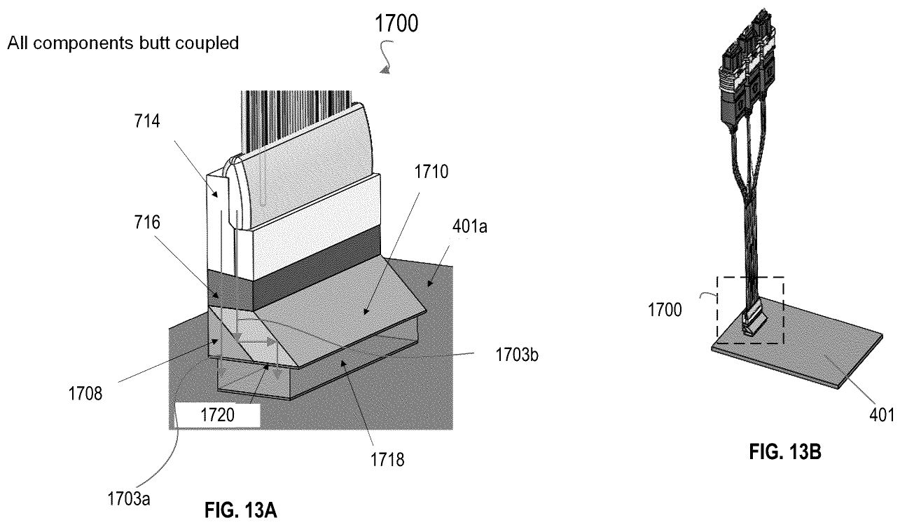

The optical assemblies described in FIGS. 5A-12 all have a horizontal configuration where the FAU is aligned to emit light in a direction parallel to the surface of the PIC. However, other configurations are possible. An example of a vertical configuration is shown in FIGS. 13A and 13B. Here, an optical assembly 1700 is composed of several components cemented together into an integrated block. These include the lens array 716 (with 1×N lenses), a wedge prism 1708, a trapezoidal plate 1710, spacer/polarization rotator 1720, and a second lens array (with 2×N lenses) 1718. The interface between the wedge prism 1708 and plate 1710 form a PBS and the opposite surface of the plate 1710 is a reflector.

Light emitted from the fibers of the FAU 714 propagate towards the surface 401a of the PIC. After being collimated by lenses of the lens array 716, the s-polarized light is transmitted through the PBS while the p-polarized light is reflected and traverses plate 710 before being reflected by the reflector surface back towards the PIC. The path of the s-polarized light is shown as arrow 1703a and the path of the p-polarized light is shown by an arrow 1703b. The PBS and reflector spatially separate the two components which are focused by lens array 1718 onto respective photonic ports on the surface of the PIC.

A vertical configuration, such as the assembly 1700′s configuration, can be more robust against external forces acting in the vertical direction, compared to horizontal configurations. In addition, the vertical configuration can have a smaller coupling interface with the PIC 401, which allows for a more compact system configuration and an increased packaging density.

Further, as noted above, the butt coupling of components in the assembly 1700 can provide some advantages, including increasing coupling efficiency by aligning optical elements in direct contact and enhance the transfer of optical power between them. It may also reduce the reflections at the interface and thus reduce signal loss. In addition, it allows for a compact design.

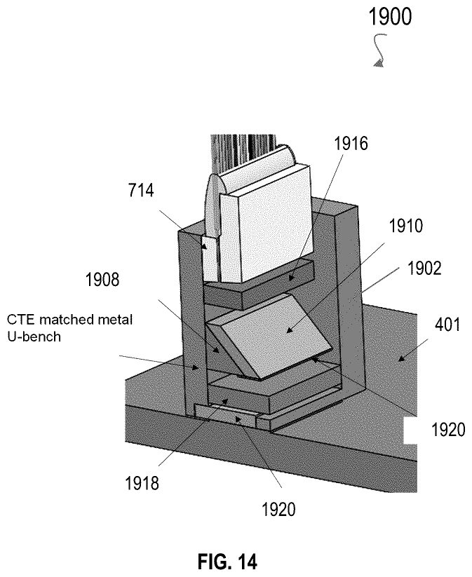

Vertically configured assemblies can also include components that are spaced apart, rather than butt coupled into an integrated package. For example, referring to FIG. 14, an example assembly 1900 includes the FAU 714, a lens array 1916 spaced from the FAU, and an optical block spaced from the lens array 1916. The lens array includes a wedge prism 1908 and a trapezoidal plate 1910, similar to prism 1708 and plate 1710 described above, which provide interfaces for the PBS and a reflector. A polarization rotator 1920 is bonded to the lower surface of the plate 1910. A second lens array 1918 is spaced apart from the optical block. The assembly is mounted in a housing 1902 composed of a U-bench and a window 1920, facing the surface of the PIC. As noted above, this configuration with free space between some optical components can provide some advantages, such as greater alignment tolerance, reduced contamination risk, and greater flexibility for component interchangeability.

While the assemblies 1700 and 1900 are vertically configured so that light from the fibers are incident on the surface of the PIC nominally perpendicular (the focused light will subtend a cone with an axis approximately perpendicular to the surface), in some examples an optical assembly can be configured to deliver light at non-perpendicular incidence. For example, assemblies can include a slanted surface to mount the assembly off-perpendicular, e.g., so that the incident beams have a nominal incidence angle in a range that is greater than 0° but less than 45°, such as in a range from 5° to 20°, from 5° to 15°, from 5° to 10°, such as about 7°.

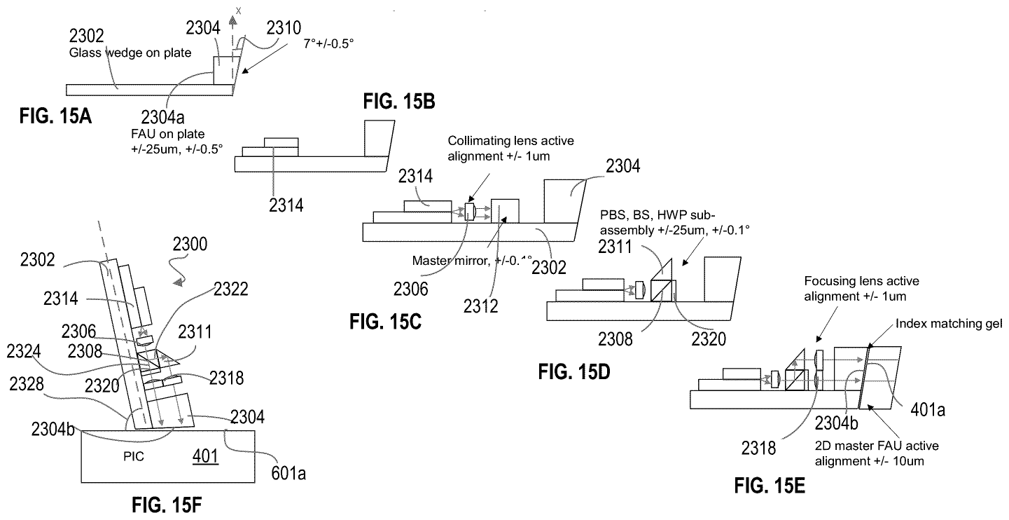

Referring to FIGS. 15A to 15F, fabrication of an example assembly 2300 for mounting in a non-perpendicular configuration can include the following steps. As illustrated in FIG. 15A, a glass wedge 2304 is initially bonded to a plate 2302. The glass wedge 2304 is positioned at an edge of the plate 2302, with the edge surfaces aligned. The aligned edge surfaces form a continuous planar surface that is non-perpendicular to the plane of the plate 2302. This angle, shown as angle 2310 in FIG. 23A, corresponds to the ultimate incidence angle of the beams on the surface of the PIC. In some implementations, the first inclined angle is in a range of 6.5° and 7.5°.

Next, as illustrated in FIG. 15B, an FAU 2314 is attached to the plate 2302 at the opposite end from glass wedge 2304. Generally, the alignment during the attachment process should be within a threshold alignment accuracy. In some examples, the alignment tolerance is between −25 microns and +25 microns. The angular alignment tolerance can be within ±0.5 degree. In some implementations, attaching optical components to the glass plate 2302 involves using an index matching gel or UV-curable adhesives.

As illustrated in FIG. 15C, a 1×N lens array 2306 and a mirror 2312 are mounted to the plate 2302 between the FAU 2314 and the glass wedge 2304. The lens array 106 can have an alignment tolerance of ±1 micron. The mirror 2312 can have an angular alignment tolerance of ±1 degree of the desired angle.

As illustrated in FIG. 15D, a beam splitter 2308, a reflector 2311, a polarization rotator 2320 are attached to the mirror 2312. They can have an alignment tolerance within ±25 microns of the desired position and within ±0.1 degree of the desired angle.

As illustrated in FIG. 15E, a 2×N lens array 2318 is attached to the plate 2302 between the polarization rotator 2320 and the glass wedge 2304. The lens array 2318 can have an alignment tolerance within ±1 micron.

Attaching the assembly 2300 to the PIC 401 involves coupling a first surface 2304b of the glass wedge 2304 to a top surface 401a of the PIC 401. The alignment tolerance between the assembly 2300 to the PIC 401 can be within ±10 microns. An index matching gel or adhesive is used between the glass wedge 2304 and the PIC 401.

As illustrated in FIG. 15F, the FAU 2314, the lens array 2306, the beam splitter 2308, the reflector 2311, the polarization rotator 2320, and the lens array 2318 are arranged with air gaps separating some of these components. The glass wedge 2304 is between the lens array 2318 and the PIC 401. During operation, unpolarized light emitted from the FAU 2314 is collimated by lens array 2306 before being split into s-pol and p-pol at PBS 2308. The p-pol beam 2324 is transmitted by the PBS and is rotated to become s-pol light by the polarization rotator 2320. The s-pol beam 2322 is reflected by the PBS 2308 and the reflector 2311 and emerges from the reflector parallel to the beam 2324. Both beams are focused by the lens array 2318 through the glass wedge 2304 onto photonic ports at the surface of the PIC. Once mounted, the entire assembly 2300 is attached to the surface of the PIC 401 at an inclined angle 2328 less than 90° (e.g., between 75° and) 90°.

The assemblies described above can include one or more kinematic alignment features (e.g., kinematically adjustable actuators) to facilitate the alignment of each optical channel to its corresponding photonic port. For example, an assembly can include actuators for kinematic adjustment of the assembly along at least one axis (e.g., two axes, three axes, four axes, five axes, or six axes). In some cases, kinematic adjustment along at least one linear axis and at least one rotation axis is possible. The actuators can be manually adjusted actuators, e.g., for adjustment by a hex-key or screw adjustment. Alternatively, or additionally, in some implementations at least one of the actuators can be an active actuator, e.g., that provides electro-mechanical adjustment along at least one axis.

The optical assemblies described previously can, in certain implementations be arranged as a pair of subassemblies that can be attached and detached from each other in a way that facilitates quick assembly or replacement of one part of the assembly with another. One of the subassemblies can be securely affixed to the PIC while the other can be quickly connected or disconnected. The subassemblies can include registration features that guide the alignment of the optical components so that the complete optical assembly is properly aligned for use upon attachment of one subassembly with another. One or both of the subassemblies can include one or more actuators for kinematic adjustment.

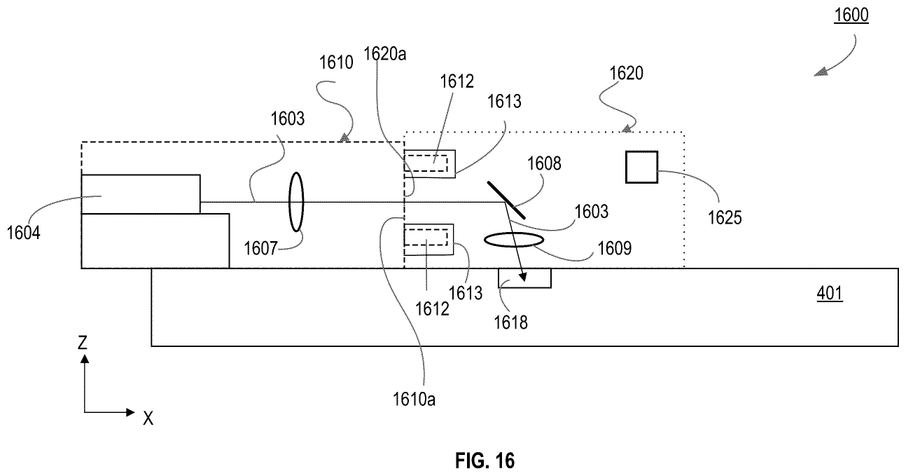

Referring to FIG. 16, this principal is embodied in an assembly 1600, which includes a detachable sub-assembly 1610 (enclosed by dashed lines) and a fixed sub-assembly 1620 (enclosed by dotted lines). The sub-assembly 1610 is detachably coupled to the sub-assembly 1620, which is fixed to the PIC 401. The sub-assembly 1620 can be fixed to the PIC 401 by, for example, flip chip bonding, adhesive bonding, or other mechanical attachment. The sub-assembly 1620 includes a kinematic actuator 1625 that allows for kinematic adjustment of optics in the subassembly to the photonic ports on the PIC 401.

The detachable sub-assembly 1610 includes a FAU 1604, which connects to an array of optical fibers. Both sub-assemblies include optical elements to shape and guide light propagating along a path 1603 between the FAU 1604 in the array and a photonic port 1618 at the surface of the PIC 401. As shown, sub-assembly 1610 includes a lens 1607 and sub-assembly 1620 includes a reflector 1608 and a lens 1609. The sub-assembly 1610 includes an interface 1610a with a pair of protruding connecting pins 1612, which mate with corresponding sockets 1613 in the sub-assembly 1620. Other implementations can have more or fewer pins and/or additional pins arranged at different locations of the interface along the Y-axis. Generally, the pins and sockets are arranged to not obscure the optical path 1603 and to provide a robust connection between the sub-assemblies with sufficient alignment accuracy to reliably align the optical elements in the two sub-assemblies along the path 1603. Moreover, the sub-assemblies can be connected by hand, without any special tooling or machine alignment. The sub-assemblies can also facilitate easy replacement of optical components in the assembly, such as a lens array, PBS, or the FAU, without having to realign optics with the photonic ports of the PIC upon replacement.

The interfaces can provide translational alignment along one or more axes to an accuracy of 20 microns or less, e.g., 15 microns or less, 10 microns or less, such as about 5 microns. The interfaces can provide angular alignment to within 0.3° or less, e.g., 0.2° or less, 0.1° or less, 0.05° or less, such as about 0.02°.

While the present example includes pins exclusively on the first sub-assembly and sockets exclusively on the second sub-assembly, other implementations are possible. For example, the second sub-assembly can include exclusively pins or both sub-assemblies can include both pins and sockets. Generally, the pins and sockets can be provided in any suitable pattern and can have any shape suitable for facilitating secure and precise attachment. For example, the pins can be cylindrical, conical, or have a polygonal (e.g., square, rectangular, cross-shaped) or other cross-sectional shape (e.g., a segment of a circle). In certain examples, the pins can have length on the order of 0.1 mm to 10 mm and an aspect ratio in a range from 0.1 to 10 (e.g., cross-sectional dimension of 0.05 mm to 1 mm). The pins can be formed from any material that has suitable mechanical strength and is compatible with fabrication techniques that yield sufficient precision for alignment of the sub-assemblies. In some examples, the pins can be formed from a metal (e.g., aluminum or copper) or metals (e.g., a metal alloy, e.g., steel), a polymer, or a ceramic.

Furthermore, in certain examples, the connecting interfaces of sub-assemblies can include alternative mating features in addition or as an alternative to the sockets/pins. Moreover, other surfaces at the interfaces can serve as fiducial surfaces for alignment. For example, in some examples the interfaces include planar surfaces that touch each other when the sub-assemblies are connected, providing alignment along a corresponding axis (e.g., orthogonal to the surfaces).

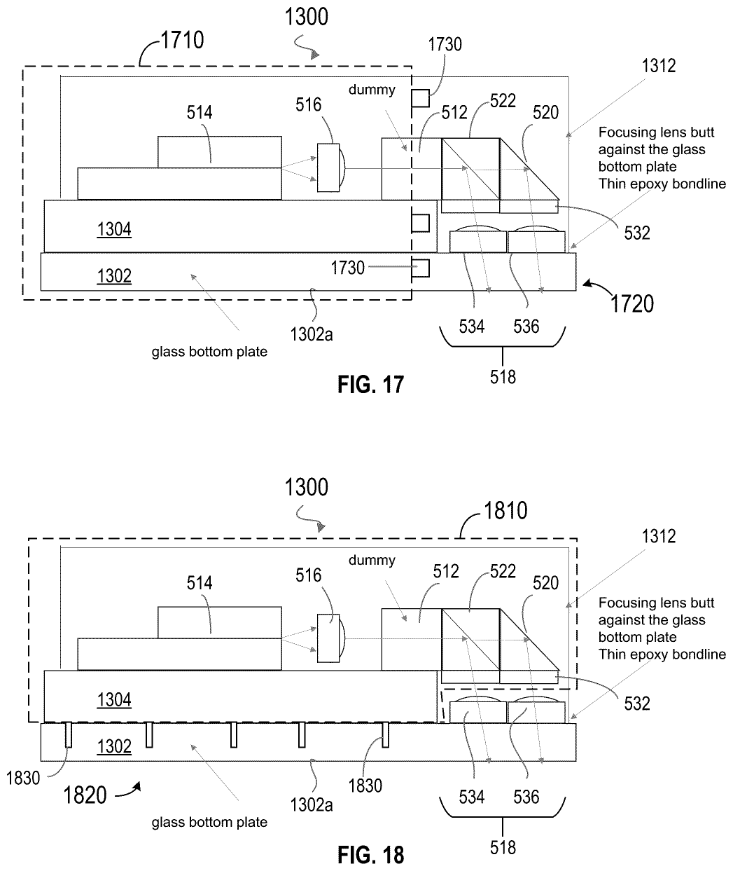

While the assembly depicted in FIG. 16 shows a single light path 1603, generally, such assemblies facilitate connection of many fibers to a PIC and each is aligned within a threshold alignment tolerance by the assembly. Moreover, the assemblies can be used to connect FAU's with using polarized or unpolarized light. Generally, any of the assemblies described previously in FIGS. 5A-15 for coupling light from non-polarizing fibers can be implemented as detachable sub-assemblies. For example, referring to FIG. 17, the assembly 1300 described previously with reference to FIG. 9 can be fabricated as sub-assemblies 1710 and 1720. Sub-assembly 1710, which is detachable from the PIC, is composed of the FAU 514, lens array 516, a portion of the spacer 512, and portions of substrates 1302 and 1304. Sub-assembly 1720, which is fixed to the PIC, includes a portion of the spacer 512, PBS 522, reflector 520, lens array 518, polarization rotator 532, and portions of substrates 1302 and 1304. Pins/sockets 1730 mate portions of the housing 1312 and the substrates 1302 and 1304.

In this configuration, the sub-assemblies connect through vertical interfaces (with respect to the PIC surface) and at a number of different components. However, in some cases, sub-assemblies can connect at horizontal interfaces. For example, referring to FIG. 18, assembly 1300 can be formed as sub-assemblies 1810 and 1820 which mate at the top surface of substrate 1302 and bottom surface of substrate 1304. Pin/sockets 1830 connect in the substrate 1302. In this example, lens array 518 is part of the fixed sub-assembly 1820 while the rest of the optical components are part of the detachable sub-assembly 1810.

Other sub-assembly divisions are possible. For example, the interface can include both horizontal and vertical portions, or can connect along segments defined by more complex shapes (e.g., steps, diagonal lines, and/or curves). Moreover, regarding assembly 1300, there are several alternative divisions of the optical components with respect to the two sub-assemblies. For instance, the interface can be formed between lens array 516 and spacer 512, between spacer 512 and PBS 522, between PBS 522 and reflector 520, and/or between reflector 520 and polarization rotator 532. Generally, the division of components can be selected based on which components can tolerate a larger degree of misalignment without significantly affecting optical signal transmissions.

As described herein in detail, the present disclosure includes a number of practical applications having features described herein that provide benefits and/or solve problems associated with providing a multi-node computing system with sufficient memory, processing, bandwidth, and energy efficiency constraints for effective operation of AI and/or ML models. Some example benefits are described herein with reference to various features and functionalities provided by the computing system as described. It will be appreciated that benefits explicitly described with reference to one or more examples described herein are provided by way of example and are not intended to be an exhaustive list of all possible benefits of the computing system.

For example, the various circuit packages described herein, and connections thereof may enable the construction of complex topologies of compute and memory nodes that can best serve a specific application. In a simple example, a set of photonic channels connect memory circuit packages with memory nodes (e.g., memory resources) to one or more compute circuit packages with compute nodes. The compute circuit packages, and memory circuit packages can be connected and configured in any number of network topologies which may be facilitated through the use of one or more photonic channels include optical fibers. This may provide the benefit of relieving distance constraints between nodes (compute and/or memory) and, for example, the memory circuit packages can physically be placed arbitrarily far from the compute circuit packages (within the optical budget of the photonic channels).

The various network topologies may provide significant speed and energy savings. For example, photonic transport of data is typically more efficient than an equivalent high-bandwidth electrical interconnect in an EIC of the circuit package itself. By implementing one or more photonic channels, the electrical cost of transmitting data may be significantly reduced. Additionally, photonic channels are typically much faster than electrical interconnects, and thus the use of photonic channels permits the grouping and topology configurations of memory and compute circuit packages that best serve the bandwidth and connectivity needs of a given application. Indeed, the architectural split of memory and compute networks allows each to be optimized for the magnitude of data, traffic patterns, and bandwidth of each network applications. A further added benefit is that of being able to control the power density of the system by spacing memory and compute circuit packages to optimize cooling efficiency, as the distances and arrangements are not dictated by electrical interfaces.

The described compute and memory nodes and fabric of communication links including the modulators and electrical interconnects described above provide a distributed data processing environment, which may be referred to as a fabric-based environment, on which programs can be run. A compute node or memory node in such an environment will generally have installed on it a software stack that runs on one or more processors of the node to provide an operating environment, which may be referred to as a layer, on which program software deployed to the node can run.

The compute and memory nodes of a particular environment can be homogeneous, i.e., all the compute nodes are basically the same and all the memory nodes are basically the same, or they can be heterogeneous.

A compute node has one or more processors that can perform data processing operations, e.g., by executing program instructions, by performing operations implemented in hardware or firmware, by routing a data packet through the electrical interface, or otherwise. The processors can include, for example, CPUs, accelerators of various kinds, e.g., GPUs (graphics processing units), TPUs (tensor processing units), DPUs (data processing units), or programmed FPGAs (field-programmable gate arrays) or other special purpose ASICs (application specific integrated circuits), or by a combination of two or more of them.

A compute node generally has or is directly connected electrically to local memory, e.g., HBM, DDR, L1 and L2 caches, registers and the like.

A memory node, while it may have processors to run software and may have other characteristics of a compute node, has as its primary purpose in a fabric-based environment the purpose of providing access to data, specifically, for example, for use by compute processes running on compute nodes, and to enable other nodes to read and write data over photonic channels connecting the memory node to the other nodes. The memory devices a memory node has for storing data can be of one or more types. They are connected through respective memory controllers, message routers, and photonic interfaces through which other nodes read and write data by sending messages to ports implemented on the memory node.

Compute and memory nodes can have memory devices of one or more kinds, including, for example, flash memory, read-only memory, random-access memory (RAM), static RAM, dynamic RAM (DRAM), synchronous DRAM (SDRAM), double data rate (DDR) based DRAM, or high bandwidth memory (HBM) memory, or a combination of two or more of them.

Unidirectional photonic links have a photonic transmitter at one end and a photonic receiver at the other end linked by an optical waveguide, e.g., a semiconductor waveguide or an optical fiber.

Generally, a photonic channel used in a fabric-based environment is a bidirectional photonic channel, which has at least two unidirectional photonic links that transmit in opposite directions, providing, for example, for the transmission of messages in one direction and acknowledgements in the other.

In some implementations, the nodes of a fabric-based environment include routers to route data from one node, directly or through intermediary nodes, to another. Generally, data is transferred in messages over photonic or electrical channels in response to programs executing on the nodes or to operations of memory controllers or similar devices, for example. Such messages can be sent point-to-point, when the two nodes have links directly connect them, or through routers on one or more intermediary nodes that route messages according to addressing data that is part of the messages.

In some implementations, a compute node will have multiple ports, electrical or photonic or both, each directly connected by a link or channel, e.g., bidirectional channel, to a respective other node; and the messages sent by the compute node will be routed to the messages' target nodes by a router on the compute node that directs the messages to the appropriate port on the compute node. When a data message is received over a port, the router on the receiving node will examine the message header to determine the destination node in the fabric, either the node itself or another node, and process the message accordingly.

The addressing of messages through the fabric-based environment can be implemented in a variety of ways. In some implementations, multiple methods are implemented in the same fabric-based environment. In some addressing methods, messages carry the actual address of the message destination, and routers in the fabric implement what in effect are routing tables to transmit messages toward their destination addresses. In some implementations, the routing tables are updated dynamically in response to information about device failures or losses of connections, for example. In other addressing methods, messages are routed by relative addresses, i.e., addresses expressed as directional steps from the current node. Modeling nodes as points on a 2D, 3D, or higher dimensional grid, a target destination can be represented in a message header as a number of steps, which may be positive, negative, or zero, in each of the dimensions. When a message has been transmitted, the receiving node can update the message header of the message to account for the steps taken by the message from the sender in each dimension, with the result that the message header now contains a relative address relative to the receiving node. In other addressing methods, a combination of direct and relative addresses is used.

Memory nodes can be interconnected by photonic links, e.g., in the form of bidirectional photonic channels, to form a memory fabric. The memory fabric can be part of a server and generally includes multiple nodes in one or more packages. A package can include hundreds of nodes extending in multiple dimensions. A fabric made up of multiple packages can have hundreds of thousands of nodes or more, connected by photonic channels in a 2D, 3D, or higher dimensional memory fabric when the nodes have a sufficient number of photonic ports.

Generally, a fabric-based environment is implemented using packages of nodes. A package, sometimes called a System in Package (SiP), includes multiple nodes that are interconnected potentially both at an electrical layer of the package and on an interconnection substrate, e.g., a PIC, and which can be enclosed in a single casing. Each of the nodes in a package can have electrical connections, photonic connections, or both to other nodes within the package. Connections within a package are referred to as intra-chip connections, with the substrate being considered a chip. Connections between nodes in different packages are referred to as inter-chip connections.

In an environment with multiple packages, some, or all of the nodes in one package have inter-chip photonic connections to nodes in one or more other packages. Generally, these inter-chip photonic connections are made by bidirectional photonic channels.

Generally, a program that runs on a fabric-based environment will be made up of program modules, each constructed to run on one of the nodes of the environment. Generally, each module includes instructions to invoke the services of the software stack on which it is running or of the underlying physical devices of the node, to load and store data, locally or remotely, to perform computing and control operations, and to communicate and coordinate with other modules of the program running on the same node or on other nodes on which the program has also been deployed.

Each of the one or more modules that make up a program can be coded separately for a respective particular kind of node. Or a large program can be broken up automatically, e.g., by a compiler, into separately deployable components to run on the nodes of a fabric-based environment. The environment and the resources available in its nodes and the characteristics of its connections, are described by a physical topology, to define, for example, the target for which the compiler is generating executable code.

A program or the modules of a program can generally be programmed using any suitable procedural, interpreted, or declarative language, or combinations of them, from which executable or interpretable code is automatically generated, e.g., by a compiler, to run on some run-time environment, for example, on some node hardware or some software layer or layers installed on the hardware.

A physical topology generally describes the locations of the nodes, any intra-chip connections, and inter-chip connections each node has to other nodes. In some fabric-based environments, nodes are implemented in packages, and the location of a node may also include the package in which it is found. A physical topology may be stored in a topology file that defines an environment for a compiler or for deployment management software.

Program modules and components of the software stack will generally be deployed to nodes through electrical links from a control computer, which may be one of the nodes of the fabric-based environment programmed to perform this function, or which may be a separate control computer. These links can be direct or indirect, and may be provided by an electrical bus, e.g., a PCIe (Peripheral Component Interconnect Express) bus. In some implementations, the photonic links of the fabric-based environment may also be used to deploy modules and components to nodes.

Executable code can be deployed to nodes directly, or, for example, in containers which can be managed by a container management or orchestration system.

A fabric-based environment will generally include one or more nodes that are connected, or can be connected dynamically, to devices external to the fabric. External devices can include devices, for example, to provide human interaction for programs running on the fabric, or to provide data to, or to receive results from, such programs.

The fabric-based environment can be or be part of a general computing environment for executing programs. The computing environment can include or be associated with a compilation environment. The compilation environment takes a program input, e.g., an input machine learning model, and transforms it into machine-readable form by executing a compiler and a code generator. An input machine learning model can be provided in the form of a TensorFlow model, for example.

The application code generated by the compiler and code generator is, in some implementations, provided to a runtime environment running on the nodes of the computing environment. The runtime environment provides services to the running application code on the computing environment. In some implementations, the nodes of the computing environment include firmware that performs hardware-related operations, e.g., monitoring and driving hardware components of the computing environment, used by the runtime environment and the application code.

The application and runtime environment run on the compute nodes and use, if and as requested by the application, the resources of the fabric-based environment, including, for example, the compute nodes, memory nodes, memory devices, links and channels, routers, and ports.

As discussed herein in detail, the present disclosure includes a number of practical applications having features described herein that provide benefits and/or solve problems associated with providing a multi-node computing system with sufficient memory, processing, bandwidth, and energy efficiency constraints for effective operation of AI and/or ML models. Some example benefits are discussed herein in connection with various features and functionalities provided by the computing system as described.

For example, the various circuit packages described herein, and connections thereof may enable the construction of complex topologies of compute and memory nodes that can best serve a specific application. In a simple example, a set of photonic channels connect memory circuit packages with memory nodes (e.g., memory resources) to one or more compute circuit packages with compute nodes. The compute circuit packages, and memory circuit packages can be connected and configured in any number of network topologies which may be facilitated through the use of one or more photonic channels include optical fibers. This may provide the benefit of relieving distance constraints between nodes (compute and/or memory) and, for example, the memory circuit packages can physically be placed arbitrarily far from the compute circuit packages (within the optical budget of the photonic channels).

The various network topologies may provide significant speed and energy savings. For example, photonic transport of data is typically more efficient than an equivalent high-bandwidth electrical interconnect in an EIC of the circuit package itself. By implementing one or more photonic channels, the electrical cost of transmitting data may be significantly reduced.

Additionally, photonic channels are typically much faster than electrical interconnects, and thus the use of photonic channels permits the grouping and topology configurations of memory and compute circuit packages that best serve the bandwidth and connectivity needs of a given application. Indeed, the architectural split of memory and compute networks allows each to be optimized for the magnitude of data, traffic patterns, and bandwidth of each network applications. A further added benefit is that of being able to control the power density of the system by spacing memory and compute circuit packages to optimize cooling efficiency, as the distances and arrangements are not dictated by electrical interfaces.

This specification uses the term “configured to” in connection with systems, apparatus, and computer program components. That a system is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed, perform the operations or actions. That special-purpose circuitry is configured to perform particular operations or actions means that the circuitry circuit elements that, when put into operation, perform the operations or actions.

This specification uses the term “configured to” in connection with systems, apparatus, and computer program components. That a system is configured to perform particular operations or actions means that the system has installed on it software, firmware, hardware, or a combination of them that in operation cause the system to perform the operations or actions.

That one or more computer programs is configured to perform particular operations or actions means that the one or more programs include instructions that, when executed, perform the operations or actions. That special-purpose circuitry is configured to perform particular operations or actions means that the circuitry circuit elements that, when put into operation, perform the operations or actions.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one example” or “an example” of the present disclosure are not intended to be interpreted as excluding the existence of additional examples that also incorporate the recited features. For example, any element described in relation to an example herein may be combinable with any element of any other example described herein. Numbers, percentages, ratios, or other values stated herein are intended to include that value, and also other values that are “about” or “approximately” the stated value, as would be appreciated by one of ordinary skill in the art encompassed by examples of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to examples disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the examples that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The following numbered paragraphs are non-limiting examples of various embodiments of the present disclosure.

1. An assembly for surface coupling an unpolarized optical signal from an optical fiber into a pair of photonic ports on an integrated circuit (IC), including: a beam splitter arranged to receive the unpolarized optical signal from the optical fiber and split the unpolarized optical signal into a first polarized optical signal and a second polarized optical signal having a polarization state orthogonal to the first polarized optical signal; a reflector arranged in a path of the second polarized optical signal and configured to reflect the second polarized optical signal towards the PIC; a polarization rotator arranged in the path of either the first polarized optical signal or the second polarized optical signal and configured to change the polarization state of the first polarized optical signal or the second polarized optical signal polarized optical signal to the same polarization state as the second polarized optical signal or the first polarized optical signal; and a lens array arranged after the polarization rotator in the paths of the first polarized optical signal and the second polarized optical signal, the lens array including a first lens arranged to focus the first polarized optical signal onto the first photonic port and a second lens arranged to focus the second polarized optical signal onto the second photonic port, the second photonic port being displaced from the first photonic port.

2. The assembly of claim 1, wherein the first photonic port is displaced from the second photonic port by about 1 mm or less.

3. The assembly of paragraph 1, wherein the polarization rotator includes a half-wave plate.

4. The assembly of paragraph 1, wherein the beam splitter includes a polarizing beam splitter (PBS).

5. The assembly of paragraph 1, wherein the beam splitter includes a birefringent crystal, wherein the first polarized optical signal and the second polarized optical signal have different directions of propagation inside the birefringent crystal, and wherein the reflector is configured to reflect both the first polarized optical signal and the second polarized optical signal.

6. The assembly of paragraph 1, wherein the first polarized optical signal has a s-polarization state, and the second polarized optical signal has a p-polarization state.

7. The assembly of paragraph 1, wherein the first polarized optical signal has a p-polarization state, and the second polarized optical signal has a s-polarization state.

8. The assembly of paragraph 1, wherein the reflector is configured to reflect an optical signal emitted from a second photonic port in the PIC towards the beam splitter.

9. The assembly of paragraph 1, wherein the assembly includes a fiber array unit (FAU) optically coupled to the beam splitter, and wherein the FAU includes the optical fiber and additional optical fibers that collectively provide a plurality of channels including one or more transmitter channels, one or more receiver channels, one or more continuous wave optical power channels, and one or more alignment channels.

10. The assembly of paragraph 1, wherein the assembly includes a fiber array unit (FAU) optically coupled to the beam splitter and a third lens positioned in an optical path of the unpolarized optical signal between the FAU and the beam splitter and configured to collimate the unpolarized optical signal emitted from the optical fiber.

11. The assembly of paragraph 10, wherein the first and second lenses are lenses of a 2×N lens array, and the third lens is a lens of a 1×N lens array.

12. The assembly of paragraph 10, wherein the FAU, the third lens, the beam splitter and the reflector are arranged along a first direction, and the polarization rotator and the lens array are arranged along a second direction, the first direction being perpendicular to the second direction.

13. The assembly of paragraph 10, wherein the FAU, the third lens, the beam splitter, the polarization rotator, and the lens array are arranged along a first direction, and the reflector is adjacent to the beam splitter along a second direction, the first direction being perpendicular to the second direction.

14. The assembly of paragraph 1, further including one or more actuator for kinematic adjustment of the assembly relative to the photonic ports along at least one axis.

15. A system, including the assembly of paragraph 1 and the PIC, wherein the first photonic port includes a first grating coupler (GC), and the second photonic port includes a second GC.

16. The system of paragraph 16, wherein the first GC is coupled to a first input end of a photodetector (PD) through a first waveguide of the pair of waveguides, and the second GC is coupled to a second input end of the PD through a second waveguide of the pair of waveguides, the PD being in the PIC.

17. The system of paragraph 17, wherein the pair of waveguides are configured to compensate an optical path displacement between the first polarized optical signal and the second polarized optical signal that are caused at least partially by the beam splitter and the reflector. 18. The system of paragraph 18, wherein the first waveguide and the second waveguide are configured such that a first input optical signal at the first input end of the PD and a second input optical signal at the second input end of the PD have identical frequency and net group delay from the fiber to the PD the first input optical signal being associated with the first polarized optical signal and the second input optical signal being associated with the second polarized optical signal.

19. The system of paragraph 16, wherein the first photonic port is coupled to an input end of a modulator through a first waveguide of the pair of waveguides, the modulator being configured to code data into the first polarized optical signal to generate a modulated optical signal.

20. A method including: providing a photonic integrated circuit (PIC) including a first photonic port, a second photonic port and a pair of waveguides; providing an assembly, the assembly including: a beam splitter arranged to receive an unpolarized optical signal from an optical fiber and split the unpolarized optical signal into a first polarized optical signal and a second polarized optical signal having a polarization state orthogonal to the first polarized optical signal; a reflector arranged in a path of the second polarized optical signal configured to reflect the second polarized optical signal towards the PIC; a polarization rotator arranged in the path of the second polarized optical signal and configured to change the polarization state of the second polarized optical signal to the same polarization state as the first polarized optical signal; and a lens array arranged in the paths of the first polarized optical signal and the second polarized optical signal, the lens array including a first lens arranged to focus the first polarized optical signal onto the first photonic port in a surface of the PIC, the lens array further including a second lens arranged to focus the second polarized optical signal onto the second photonic port in the surface of the PIC, the second photonic port being displaced from the first photonic port and each photonic port being optically coupled to a corresponding one waveguide of the pair of waveguides; and attaching the assembly to the PIC with the lens array aligned with the photonic ports.

21. The method of paragraph 20, wherein the assembly further includes: a glass wedge on a plate along a first direction; an optical interface configured to connect to a light source; a third lens arranged in a path of the unpolarized optical signal and configured to focus the unpolarized optical signal from the optical interface into the beam splitter, the optical interface, the third lens, the beam splitter, the polarization rotator and the lens array being positioned on the plate and adjacent to the glass wedge along a second direction, the second direction being perpendicular to the first direction, and attaching the assembly to the PIC includes: coupling a first surface of the glass wedge with the surface of the PIC.

22. The method of paragraph 21, wherein the first surface of the glass wedge has an inclined angle with respective to the first direction.

23. The method of paragraph 21, wherein the optical interface includes a fiber array unit (FAU).

24. The method of paragraph 21, wherein the inclined angle is between about 6.5 degrees and about 7.5 degrees.

25. The method of paragraph 21, wherein coupling the first surface of the glass wedge with the surface of the PIC includes: providing an index matching gel between the glass wedge and the surface of the PIC.

26. A system, including: first sub-assembly including a fiber array unit (FAU) and a first mechanical interface including one or more connectors and/or receptacles; and a second sub-assembly affixed to a photonic integrated circuit (PIC), the second sub-assembly including a first lens array and a second mechanical interface including one or more receptacles and/or connectors for mating with the connectors and/or receptacles of the first mechanical interface, the first lens array configured to focus an optical signal into a photonic port in a surface of the PIC, wherein the first assembly is detachably coupled to the second assembly by the first mechanical interface coupling to the second mechanical interface.

27. The system of paragraph 26, wherein the FAU includes a plurality of optical fibers and the first lens array includes at least one lens corresponding to each of the optical fibers.

28. The system of paragraph 2, wherein the first lens array includes two lenses of each of the optical fibers.

29. The system of paragraph 26, wherein light from a single optical fiber of the FAU is separately focused into two photonic ports in the surface of the PIC.

30. The system of paragraph 26, wherein the connectors each include a pin, and the receptacles each include a socket.

31. The system of paragraph 26, wherein the first mechanical interface includes at least a portion perpendicular to the surface of the PIC.

32. The system of paragraph 26, wherein the first mechanical interface includes at least a portion parallel to the surface of the PIC.

33. The system of paragraph 26, wherein the first and second sub-assemblies define an optical path from a fiber of the FAU to the photonic port and the connectors and/or receptacles are arranged away from the optical path.

34. The system of paragraph 26, wherein the first sub-assembly includes at least one of a second lens array, a polarizing beam splitter, a reflector, and a polarization rotator.

35. The system of paragraph 26, wherein the second sub-assembly includes at least one of a second lens array, a polarizing beam splitter, a reflector, and a polarization rotator.

36. The system of paragraph 26, wherein the first sub-assembly includes a second lens array coupled to the FAU, the second lens array being in an optical path between the FAU and the first mechanical interface, and the second sub-assembly includes a polarizing beam splitter, the beam splitter coupled to the second mechanical interface, a reflector optically coupled to the beam splitter, a polarization rotator optically coupled to at least one of the polarizing beam splitter or the reflector, and wherein the second lens array is configured to focus a second optical signal from an optical fiber into the polarizing beam splitter, the polarizing beam splitter is configured to split the second optical signal into two optical signals with differing polarization states, the reflector is configured to reflect at least one of the optical signals towards the PIC, and the polarization rotator is configured to change a polarization state of one of the optical signals.

37. The system of paragraph 26, wherein the first sub-assembly includes a second lens array optically coupled to the FAU, the second lens array being in an optical path between the FAU and a first spacer in the optical path, a surface of the first spacer defining at least a portion of the first mechanical interface, and wherein the second sub-assembly includes a second spacer, a surface of the second spacer defining at least a portion of the second mechanical interface.

38. The system of paragraph 37, wherein the second sub-assembly further includes a polarizing beam splitter optically coupled to the second spacer, a reflector optically coupled to the polarizing beam splitter, a polarization rotator optically coupled to at least one of the polarizing beam splitter or the reflector, and wherein the second lens array is configured to focus a second optical signal from an optical fiber into the polarizing beam splitter, the polarizing beam splitter is configured to split the second optical signal into two optical signals with differing polarization states, the reflector is configured to reflect at least one of the optical signals towards the PIC, and the polarization rotator is configured to change a polarization state of one of the optical signals.

39. The system of paragraph 26, wherein the first sub-assembly includes a first glass substrate, a surface of the first glass substrate defining at least a portion of the first mechanical interface, a second lens array on the first glass substrate, a polarizing beam splitter optically coupled to the second lens array, a reflector optically coupled to the beam splitter, a polarization rotator optically coupled to at least one of the beam splitter or the reflector, and wherein the second sub-assembly includes a second glass substrate, the first lens array being supported by the second glass substrate, a surface of the second glass substrate defining at least a portion of the second mechanical interface, and wherein the second lens array is configured to focus a second optical signal from an optical fiber into the beam splitter, the polarizing beam splitter is configured to split the second optical signal into two optical signals with differing polarization states, the reflector is configured to reflect at least one of the optical signals towards the PIC, and the polarization rotator is configured to change a polarization state of one of the optical signals.

40. The system of paragraph 26, wherein the first sub-assembly includes a second lens array optically coupled to the FAU, the second lens array being configured to collimate light emitted from fibers of the FAU and focus light from the PIC onto fibers of the FAU.

41. The system of paragraph 40, wherein the second lens array forms at least a portion of the first mechanical interface.

42. The system of paragraph 26, further including one or more actuator for kinematic adjustment of the assembly relative to the photonic ports along at least one axis.

43. A system, including: a first sub-assembly including: a fiber array unit (FAU) including a plurality of optical fibers; a polarizing beam splitter arranged to receive an unpolarized optical signal from the FAU and split the unpolarized optical signal into a first polarized optical signal and a second polarized optical signal having a polarization state orthogonal to the first polarized optical signal; a reflector arranged in a path of the second polarized optical signal and configured to reflect at least one of the first polarized optical signal or the second polarized optical signal towards a photonic integrated circuit (PIC); a polarization rotator arranged in the path of the second polarized optical signal and configured to change the polarization state of the second polarized optical signal to the same polarization state as the first polarized optical signal; a lens array arranged in the paths of the first polarized optical signal and the second polarized optical signal, the lens array arranged to focus the first polarized optical signal onto a first photonic port in a surface of the PIC and focus the second polarized optical signal onto a second photonic port in the surface of the PIC; and a first mechanical interface, the first interface including at least one of a connector or a receptacle; and a second sub-assembly fixedly attached to the PIC, the second sub-assembly including a second mechanical interface having at least one of a corresponding connector or a corresponding receptacle, wherein the first assembly is detachably coupled to the second assembly with the at least one of the connector or the receptacle coupled with the at least one of the corresponding connector or the corresponding receptacle.

44. A system, including: first sub-assembly including a fiber array unit (FAU) and a first mechanical interface including one or more connectors and/or receptacles; and a second sub-assembly affixed to a photonic integrated circuit (PIC), the second sub-assembly including a first lens array, a second mechanical interface, and one or more kinematic alignment features for kinematic adjustment of the second sub-assembly relative to the PIC and/or the first sub-assembly, the first lens array configured to focus an optical signal into a photonic port in a surface of the PIC, wherein the first assembly is passively coupled to the second assembly by the first mechanical interface coupling to the second mechanical interface.

45. A system, including: a first sub-assembly including: a fiber array unit (FAU) including a plurality of optical fibers; a polarizing beam splitter arranged to receive an unpolarized optical signal from the FAU and split the unpolarized optical signal into a first polarized optical signal and a second polarized optical signal having a polarization state orthogonal to the first polarized optical signal; a reflector arranged in a path of the second polarized optical signal and configured to reflect at least one of the first polarized optical signal or the second polarized optical signal towards a photonic integrated circuit (PIC); a polarization rotator arranged in the path of the second polarized optical signal and configured to change the polarization state of the second polarized optical signal to the same polarization state as the first polarized optical signal; a lens array arranged in the paths of the first polarized optical signal and the second polarized optical signal, the lens array arranged to focus the first polarized optical signal onto a first photonic port in a surface of the PIC and focus the second polarized optical signal onto a second photonic port in the surface of the PIC; a first mechanical interface; and at least one kinematic alignment feature; and a second sub-assembly fixedly attached to the PIC, the second sub-assembly including a second mechanical interface, wherein the first assembly is passively coupled to the second assembly.

Particular implementations of the subject matter have been described. Other implementations are within the scope of the following claims.

What is claimed is:

1. A system, comprising:
first sub-assembly comprising a fiber array unit (FAU) and a first mechanical interface comprising one or more connectors and/or receptacles; and
a second sub-assembly affixed to a photonic integrated circuit (PIC), the second sub-assembly comprising a first lens array and a second mechanical interface comprising one or more receptacles and/or connectors for mating with the connectors and/or receptacles of the first mechanical interface, the first lens array configured to focus an optical signal into a photonic port in a surface of the PIC,
wherein the first assembly is detachably coupled to the second assembly by the first mechanical interface coupling to the second mechanical interface.

2. The system of claim 1, wherein the FAU comprises a plurality of optical fibers and the first lens array comprises at least one lens corresponding to each of the optical fibers.

3. The system of claim 2, wherein the first lens array includes two lenses of each of the optical fibers.

4. The system of claim 1, wherein light from a single optical fiber of the FAU is separately focused into two photonic ports in the surface of the PIC.

5. The system of claim 1, wherein the connectors each comprise a pin, and the receptacles each comprise a socket.

6. The system of claim 1, wherein the first mechanical interface comprises at least a portion perpendicular to the surface of the PIC.

7. The system of claim 1, wherein the first mechanical interface comprises at least a portion parallel to the surface of the PIC.

8. The system of claim 1, wherein the first and second sub-assemblies define an optical path from a fiber of the FAU to the photonic port and the connectors and/or receptacles are arranged away from the optical path.

9. The system of claim 1, wherein the first sub-assembly comprises at least one of a second lens array, a polarizing beam splitter, a reflector, and a polarization rotator.

10. The system of claim 1, wherein the second sub-assembly comprises at least one of a second lens array, a polarizing beam splitter, a reflector, and a polarization rotator.

11. The system of claim 1, wherein the first sub-assembly comprises a second lens array coupled to the FAU, the second lens array being in an optical path between the FAU and the first mechanical interface, and the second sub-assembly comprises a polarizing beam splitter, the beam splitter coupled to the second mechanical interface, a reflector optically coupled to the beam splitter, a polarization rotator optically coupled to at least one of the polarizing beam splitter or the reflector, and
wherein the second lens array is configured to focus a second optical signal from an optical fiber into the polarizing beam splitter, the polarizing beam splitter is configured to split the second optical signal into two optical signals with differing polarization states, the reflector is configured to reflect at least one of the optical signals towards the PIC, and the polarization rotator is configured to change a polarization state of one of the optical signals.

12. The system of claim 1, wherein the first sub-assembly comprises a second lens array optically coupled to the FAU, the second lens array being in an optical path between the FAU and a first spacer in the optical path, a surface of the first spacer defining at least a portion of the first mechanical interface, and wherein the second sub-assembly comprises a second spacer, a surface of the second spacer defining at least a portion of the second mechanical interface.

13. The system of claim 12, wherein the second sub-assembly further comprises a polarizing beam splitter optically coupled to the second spacer, a reflector optically coupled to the polarizing beam splitter, a polarization rotator optically coupled to at least one of the polarizing beam splitter or the reflector, and
wherein the second lens array is configured to focus a second optical signal from an optical fiber into the polarizing beam splitter, the polarizing beam splitter is configured to split the second optical signal into two optical signals with differing polarization states, the reflector is configured to reflect at least one of the optical signals towards the PIC, and the polarization rotator is configured to change a polarization state of one of the optical signals.

14. The system of claim 1, wherein the first sub-assembly comprises a first glass substrate, a surface of the first glass substrate defining at least a portion of the first mechanical interface, a second lens array on the first glass substrate, a polarizing beam splitter optically coupled to the second lens array, a reflector optically coupled to the beam splitter, a polarization rotator optically coupled to at least one of the beam splitter or the reflector, and wherein the second sub-assembly comprises a second glass substrate, the first lens array being supported by the second glass substrate, a surface of the second glass substrate defining at least a portion of the second mechanical interface, and
wherein the second lens array is configured to focus a second optical signal from an optical fiber into the beam splitter, the polarizing beam splitter is configured to split the second optical signal into two optical signals with differing polarization states, the reflector is configured to reflect at least one of the optical signals towards the PIC, and the polarization rotator is configured to change a polarization state of one of the optical signals.

15. The system of claim 1, wherein the first sub-assembly comprises a second lens array optically coupled to the FAU, the second lens array being configured to collimate light emitted from fibers of the FAU and focus light from the PIC onto fibers of the FAU.

16. The system of claim 15, wherein the second lens array forms at least a portion of the first mechanical interface.

17. The system of claim 1, further comprising one or more actuator for kinematic adjustment of the assembly relative to the photonic ports along at least one axis.

18. A system, comprising:
a first sub-assembly comprising:
a fiber array unit (FAU) comprising a plurality of optical fibers;
a polarizing beam splitter arranged to receive an unpolarized optical signal from the FAU and split the unpolarized optical signal into a first polarized optical signal and a second polarized optical signal having a polarization state orthogonal to the first polarized optical signal;
a reflector arranged in a path of the second polarized optical signal and configured to reflect at least one of the first polarized optical signal or the second polarized optical signal towards a photonic integrated circuit (PIC);
a polarization rotator arranged in the path of the second polarized optical signal and configured to change the polarization state of the second polarized optical signal to the same polarization state as the first polarized optical signal;
a lens array arranged in the paths of the first polarized optical signal and the second polarized optical signal, the lens array arranged to focus the first polarized optical signal onto a first photonic port in a surface of the PIC and focus the second polarized optical signal onto a second photonic port in the surface of the PIC; and
a first mechanical interface, the first interface comprising at least one of a connector or a receptacle; and
a second sub-assembly fixedly attached to the PIC, the second sub-assembly comprising a second mechanical interface having at least one of a corresponding connector or a corresponding receptacle,
wherein the first assembly is detachably coupled to the second assembly with the at least one of the connector or the receptacle coupled with the at least one of the corresponding connector or the corresponding receptacle.
